(19) United States
(12) Patent Application Publication
(10) Pub. No.: US 2026/0080912 A1
(43) Pub. Date: Mar. 19, 2026

(54) SEMICONDUCTOR CIRCUIT, MEMORY DEVICE, AND MEMORY SYSTEM

(71) Applicant: Kioxia Corporation, Tokyo (JP)

(72) Inventor: Tetsuya INOUE, Fujisawa Kanagawa (JP)

(73) Assignee: Kioxia Corporation, Tokyo (JP)

(21) Appl. No.: 19/072,423

(22) Filed: Mar. 6, 2025

(30) Foreign Application Priority Data
Sep. 18, 2024 (JP) 2024-161116

(51) Int. Cl. G11C 5/06

(52) U.S. Cl. CPC G11C 5/063

(57) ABSTRACT

According to one embodiment, a semiconductor circuit includes: a detection unit that detects a first signal waveform of a first input signal on a first communication path and a second signal waveform of a second input signal on a second communication path, which is different from the first communication path; a signal generation unit that generates a control signal based on the detected first and second signal waveforms; and a first driver unit that outputs an output signal corresponding to the first input signal at a driver strength based on the control signal.

### CROSS-REFERENCE TO RELATED APPLICATIONS

This application is based upon and claims the benefit of priority from Japanese Patent Application No. 2024-161116, filed Sep. 18, 2024, the entire contents of which are incorporated herein by reference.

### FIELD

Embodiments described herein relate generally to a semiconductor circuit, a memory device, and a memory system.

### BACKGROUND

An interface circuit that performs high-speed parallel communication is applied to an information processing system.

### BRIEF DESCRIPTION OF DRAWINGS

FIG. 1 is a block diagram illustrating a configuration example of an information communication system including a semiconductor circuit according to an embodiment.

FIG. 2 is a block diagram for illustrating the outline of a semiconductor circuit of the first embodiment.

FIG. 3 is a diagram for illustrating the control of a semiconductor circuit according to the first embodiment.

FIG. 4 is a timing chart illustrating an example of the operation of a semiconductor circuit according to the first embodiment.

FIG. 5 is a circuit diagram illustrating an example of the circuit configuration of a semiconductor circuit according to the first embodiment.

FIG. 6 is a schematic diagram for illustrating the characteristics of a semiconductor circuit according to the first embodiment.

FIG. 7 is a circuit diagram illustrating an example of the circuit configuration of a semiconductor circuit according to the second embodiment.

FIG. 8 is a block diagram for illustrating the outline of a semiconductor circuit of the third embodiment.

FIG. 9 is a diagram for illustrating the control of a semiconductor circuit according to the third embodiment.

FIG. 10 is a circuit diagram illustrating an example of the circuit configuration of a semiconductor circuit according to the fourth embodiment.

FIG. 11 is a circuit diagram illustrating an example of a circuit in a semiconductor circuit according to the fourth embodiment.

FIG. 12 is a circuit diagram illustrating an example of a circuit in a semiconductor circuit according to the fourth embodiment.

FIG. 13 is a circuit diagram illustrating an example of a circuit in a semiconductor circuit according to the fourth embodiment.

FIG. 14 is a circuit diagram illustrating an example of a circuit in a semiconductor circuit according to the fourth embodiment.

FIG. 15 is a diagram for illustrating the control of a semiconductor circuit according to the fourth embodiment.

FIG. 16 is a schematic diagram for illustrating the characteristics of a semiconductor circuit according to the first embodiment.

FIG. 17 is a block diagram illustrating an application example of a semiconductor circuit according to an embodiment.

### DETAILED DESCRIPTION

In general, according to one embodiment, a semiconductor circuit includes: a detection unit that detects a first signal waveform of a first input signal on a first communication path and a second signal waveform of a second input signal on a second communication path, which is different from the first communication path; a signal generation unit that generates a control signal based on the detected first and second signal waveforms; and a first driver unit that outputs an output signal corresponding to the first input signal at a driver strength based on the control signal.

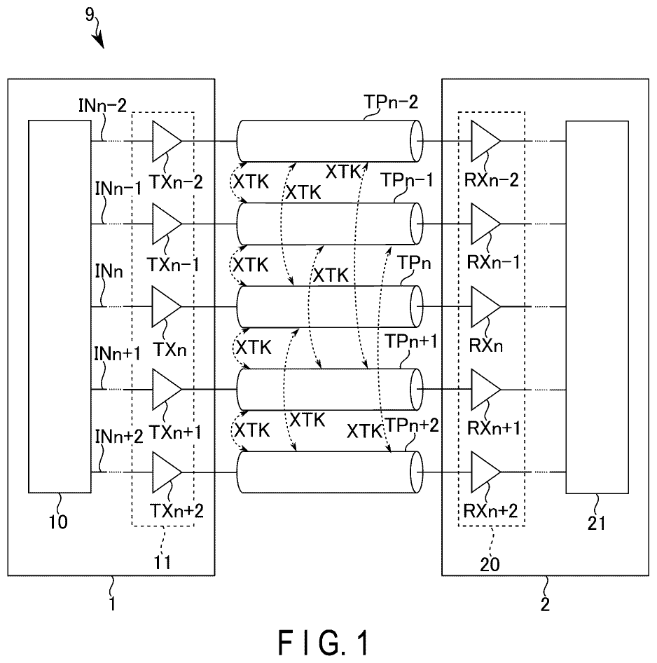

The semiconductor circuit, the memory device, and the memory system according to an embodiment will be described with reference to FIGS. 1 to 17. In the following description, elements having the same function and configuration are denoted by the same reference numeral. Further, in each of the following embodiments, in a case where components (for example, circuits, wirings, various voltages and signals, and the like) with a reference numeral accompanied by a distinguishing number/English letter at the end are not necessarily distinguished from each other, a description (reference numeral) omitting the number/English letter at the end is used.

### EMBODIMENT

### (1) First Embodiment

The semiconductor circuit according to the first embodiment will be described with reference to FIGS. 1 to 6.

### (a) Configuration Example

### (a-1) Overall Configuration

FIG. 1 is a block diagram illustrating a configuration example of an information processing system including a semiconductor circuit according to the embodiment.

An information processing system 9 includes a first device 1 and a second device 2. The first device 1 is a device on the information transmission side. The second device 2 is a device on the information reception side.

The first device 1 communicates with the second device 2 via a plurality of communication paths TP (TPn−2, TPn−1, TPn, TPn−1, and TPn−2) forming wireless or wired parallel communication.

The first device 1 includes a processing circuit 10 and a semiconductor circuit 11 of the embodiment.

The processing circuit 10 executes various types of information processing. The processing circuit 10 includes a processor, a controller, and the like. The processing circuit 10 generates a plurality of signals (data) based on a result of information processing. The processing circuit 10 sends the generated signals to the semiconductor circuit 11.

In the embodiment, the semiconductor circuit 11 is a transmission circuit 11 in the interface circuit of the device 1. The transmission circuit 11 receives the signals from the processing circuit 10. The transmission circuit 11 executes various types of processing for signal transmission on the signals from the processing circuit 10.

The transmission circuit 11 includes a plurality of transmitters TX (TXn−2, TXn−1, TXn, TXn−1, and TXn−2). Each of the transmitters TX processes a signal IN (INn−2, INn−1, INn, INn−1, and INn−2) from the processing circuit 10. The transmission circuit 11 sends information including the signals processed by each transmitter TX to the second device 2 via the communication paths TP.

The internal configuration of the transmitter TX will be described later.

The second device 2 receives information from the first device 1. The second device 2 includes a reception circuit 20 and a processing circuit 21.

The reception circuit 20 receives a plurality of signals from the transmission circuit 11 of the first device 1 via the communication paths TP. The reception circuit 20 executes various types of processing for signal reception on the signals from the transmission circuit 11. The reception circuit 20 includes a plurality of receivers RX (RXn−2, RXn−1, RXn, RXn−1, and RXn−2). Each of the receivers RX processes the signal from the corresponding transmitter TX of the transmission circuit 11. The reception circuit 20 sends the signals processed by each of the receivers RX to the processing circuit 21.

The processing circuit 21 executes various types of processing on the signals from the reception circuit 20, the processing including calculation and storage of information corresponding to the signals.

In a case where information including a plurality of signals is transferred, crosstalk XTK occurs between the communication paths TP.

In the embodiment, the transmission circuit 11 reduces jitter caused by crosstalk XTK between wirings during parallel communication by using a feed forward equalizer (FFE) circuit.

### (a-2) Transmission Circuit

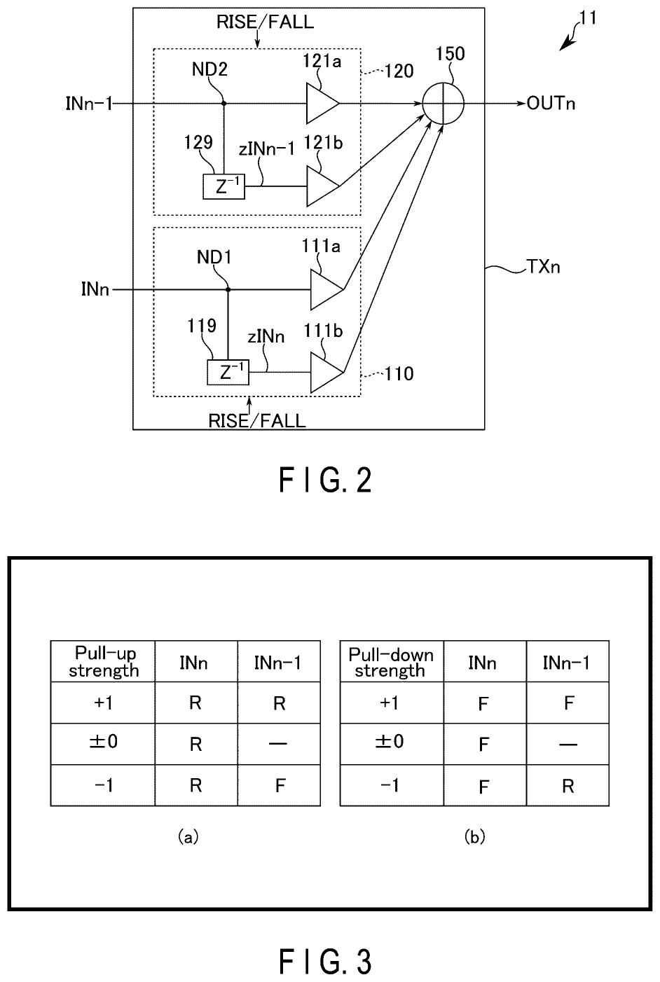

FIG. 2 is a block diagram for illustrating the outline of the transmission circuit 11 as the semiconductor circuit according to the embodiment. FIG. 2 illustrates a transmitter TXn of the transmission circuit 11 according to the embodiment.

In FIG. 2, the transmitter TXn includes a driver constituted by an FFE at the transmit end of the high-speed interface. As illustrated in FIG. 2, the transmitter TXn includes two driver circuits 110 and 120, and an adder (calculation unit) 150.

In the embodiment, the transmitter Txn acquires an output signal OUTn by using 2-bit signals INn and INn−1 on adjacent communication paths TP. The transmitter TXn receives the input signal INn to be transmitted (processed) and the input signal INn−1 on an adjacent communication path TP. The transmitter TXn sends the output signal OUTn obtained by processing the two input signals INn and INn−1 to the reception circuit 20 via the communication path TP.

Note that, in the following description, the signal INn is defined as a signal on the victim side, and the signal INn−1 is defined as a signal on the aggressor side, as the relationship of signals affected by crosstalk in the communication paths.

The driver circuit 110 includes two driver units (also referred to as buffers) 111a and 111b and a delay element (conversion filter) 119.

The input node of the driver unit 111a is connected to a node ND1. The input node of the driver unit 111a receives the input signal INn from the preceding circuit (not illustrated). The output node of the driver unit 111a is connected to the adder 150. The driver unit 111a sends the input signal INn to the adder 150. The driver unit 111a performs various processes such as amplification, attenuation, or inversion on the input signal INn.

The input node of the delay element 119 is connected to the node ND1. The input node of the delay element 119 receives the input signal INn from the preceding circuit. The output node of the delay element 119 is connected to the input node of the driver unit 111b. The delay element 119 delays the input signal INn. The delay element 119 sends the delayed input signal zINn to the driver unit 111b. The delay element 119 forms a separated path for the signal path of the input signal INn.

The driver unit 111b is provided between the delay element 119 and the adder 150 on the separated path. The input node of the driver unit 111b is connected to the delay element 119. The input node of the driver unit 111b receives the delayed input signal (hereinafter, also referred to as delay signal) zINn from the delay element 119. The output node of the driver unit 111b is connected to the adder 150. The driver unit 111b sends the delayed input signal zINn to the adder 150. The driver unit 111b performs various processes such as amplification, attenuation, or inversion on the input signal zINn.

The driver circuit 120 includes two driver units 121a and 121b and a delay element (conversion filter) 129.

The input node of the driver unit 121a is connected to a node ND2. The input node of the driver unit 121a receives the input signal INn−1 from the preceding circuit. The output node of the driver unit 121a is connected to the adder 150. The driver unit 121a sends the input signal INn−1 to the adder 150. The driver unit 121a performs various processes such as amplification, attenuation, or inversion on the input signal INn−1.

The input node of the delay element 129 is connected to the node ND2. The input node of the delay element 129 receives the input signal INn−1 from the preceding circuit. The output node of the delay element 129 is connected to the input node of the driver unit 121b. The delay element 129 delays the input signal INn−1. The delay element 129 sends the delayed input signal zINn−1 to the driver unit 121b. The delay element 129 forms a separated path for the signal path of the input signal INn−1.

The driver unit 121b is provided between the delay element 129 and the adder 150 on the separated path. The input node of the driver unit 121b is connected to the delay element 129. The input node of the driver unit 121b receives the delayed input signal zINn−1 from the delay element 129. The output node of the driver unit 121b is connected to the adder 150. The driver unit 121b sends the delayed input signal (delay signal) zINn−1 to the adder 150. The driver unit 121b performs various processes such as amplification, attenuation, or inversion on the input signal zINn−1.

The adder 150 receives the input signal INn from the driver unit 111a, the delayed input signal zINn from the driver unit 111b, the input signal INn−1 from the driver unit 121a, and the delayed input signal zINn−1 from the driver unit 121b. The adder 150 executes addition processing of the received four signals INn, zINn, INn−1, and zINn−1. The adder 150 sends the result of the addition processing of the signals INn, zINn, INn−1, and zINn−1 to the subsequent communication path TP as the output signal OUTn corresponding to the input signal INn.

As a result, regarding the input signal INn, the transmitter TXn of FFE outputs the output signal OUTn having an analog signal waveform according to the signal state of the other input signal INn−1.

The driver circuits 110 and 120 (driver units 111a, 111b, 121a, and 121b) are controlled by a control signal RISE/FALL. The control signal RISE/FALL is a signal to control the driver strength (also referred to as drive capability or drive strength) of the driver circuits 110 and 120 (driver units 111a, 111b, 121a, and 121b).

The driver strength is defined as the magnitude of a current that can flow through the driver circuit (driver unit), or as an index (degree) indicating the ability of the driver circuit to flow a current.

In the embodiment, the transmitter TXn controls the setting of the driver strength according to the change in the signal state of the input 2-bit signals (for example, 2-bit signals whose communication paths are adjacent to each other) INn and INn−1 (operation on the victim side and the aggressor side).

FIG. 3 is a diagram illustrating an example of the setting of the driver strength of the transmitter (FFE driver) TX in the transmission circuit 11 according to the embodiment.

(a) of FIG. 3 illustrates a setting example of the driver strength on the pull-up side of the driver of the transmitter TXn. (b) of FIG. 3 illustrates a setting example of the driver strength on the pull-down side of the driver of the transmitter TXn. In (a) and (b) of FIG. 3, “R” indicates that the detected signal waveform is in a rising state (rising edge), and “F” indicates that the detected signal waveform is in a falling state (falling edge). In addition, “−” indicates that the detected signal waveform is in a state fixed to the “L” level or the “H” level (non-change state).

The output signal of the transmitter TXn is affected by crosstalk XTK according to the operation on the victim side and the operation on the aggressor side. In the embodiment, in order to suppress the influence of crosstalk XTK, the transmitter TXn controls the magnitude of the driver strength.

As illustrated in (a) and (b) of FIG. 3, according to the operation on the victim side and the operation on the aggressor side, in a case where the signal waveform of the input signal INn on the victim side and the signal waveform of the input signal INn−1 on the aggressor side are both in a rising (R) state or both in a falling (F) state, the transmitter TXn is set to a strong driver strength (for example, an intensity of +1).

According to the operation on the victim side and the operation on the aggressor side, in a case where the signal waveform of the input signal INn on the victim side is different from the signal waveform of the input signal INn−1 on the aggressor side, the transmitter TXn is set to a weaker driver strength (for example, an intensity of −1) as compared with the case where the signal waveforms on the victim side and on the aggressor side are the same as each other.

In a case where there is no operation on the aggressor side and the signal waveform of the signal INn−1 on the aggressor side does not change (Case 3), the transmitter TXn sets the driver strength to the initial value (for example, an intensity of 0) without changing the driver strength, assuming that there is no influence of crosstalk XTK.

As described above, in the transmission circuit 11 of the embodiment, the transmitter TXn including an FFE driver controls the driver strength based on the change in the signal waveform of the input signals INn and INn−1 according to the operation on the victim side and the operation on the aggressor side. As a result, the transmission circuit 11 of the embodiment can reduce jitter caused by the mutual inductance between the communication paths TP in crosstalk XTK.

Note that FIG. 3 illustrates an example in which the driver strength is increased or decreased according to the operation of the victim and the aggressor. However, it may be difficult to reduce (or increase) the driver strength depending on the configuration or specification of the circuit. In such a case, the operation characteristic of the transmitter TXn may be controlled only by increasing the driver strength. Also in this case, the transmitter TXn can suppress the influence of crosstalk XTK.

As described above, the transmission circuit 11 of the embodiment generates an output signal OUTn by using the two signals INn and INn−1 that may interfere with each other. As a result, the transmission circuit 11 of the embodiment can improve the adverse effect of crosstalk XTK such as jitter.

### (b) Operation Example

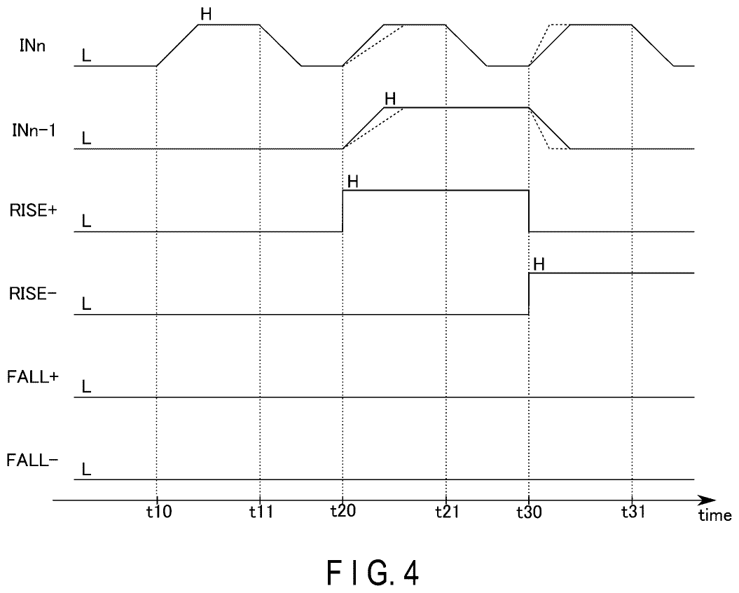

An operation example of the transmission circuit 11 of the embodiment will be described with reference to FIG. 4.

FIG. 4 is a timing chart illustrating an operation example of the transmitter TXn to which the 2-bit input signals INn and INn−1 are supplied in the transmission circuit 11 of the embodiment. FIG. 4 illustrates the signal level transition of the two input signals INn and INn−1, and the signal level transition of the control signals RISE+ and RISE−. In FIG. 4, the solid line indicates the signal waveform of the input signal IN in a case where there is no influence of crosstalk, and the broken line indicates the signal waveform of the input signal IN in a case where there is an influence of crosstalk.

In FIG. 4, the control signals RISE+, RISE−, FALL+, and FALL− are signals to control the driver strength of the transmitter TXn. The control signal RISE+ is a signal to increase the driver strength of the driver circuit on the victim side in a case where the signal level of the input signal INn on the victim side rises from the “L (low)” level to the “H (high)” level and the signal level of the input signal INn−1 on the aggressor side rises from the “L” level to the “H” level. The control signal RISE− is a signal to decrease the driver strength of the driver circuit on the victim side in a case where the signal level of the input signal INn on the victim side rises from the “L” level to the “H” level and the signal level of the input signal INn−1 on the aggressor side falls from the “H” level to the “L” level. The control signal FALL+ is a signal to increase the driver strength of the driver circuit on the victim side in a case where the signal level of the input signal INn on the victim side falls from the “H” level to the “L” level and the signal level of the input signal INn−1 on the aggressor side falls from the “H” level to the “L” level. The control signal FALL− is a signal to decrease the driver strength of the driver circuit on the victim side in a case where the signal level of the input signal INn on the victim side falls from the “H” level to the “L” level and the signal level of the input signal INn−1 on the aggressor side rises from the “L” level to the “H” level.

FIG. 4 illustrates the control of the driver strength of the driver in FIG. 3.

As illustrated in FIG. 4, the input signal INn and the input signal INn−1 are supplied to the transmitter TXn in the transmission circuit 11 of the embodiment.

At time t10, the signal level of the input signal INn rises from the “L” level to the “H” level. At time t11, the signal level of the input signal INn falls from the “H” level to the “L” level.

In the period from time t10 to time t11, the signal level of the input signal INn−1 is maintained at the “L” level without being changed.

In the period from time t10 to time t11, the input signal INn−1 on the aggressor side does not change. Therefore, the influence of crosstalk does not occur on the input signal INn on the victim side. Therefore, in the period from time t10 to time t11, the control of the driver strength by the control signals RISE+ and RISE− is not executed. The signal level of the control signals RISE+ and RISE− is maintained at the “L” level. As a result, the driver strength of the transmitter TXn is maintained in the initial state (0).

At time t20, the signal level of the input signal INn rises from the “L” level to the “H” level. At the same time, at time t20, the signal level of the input signal INn−1 rises from the “L” level to the “H” level. In a case where both of the two input signals INn and INn−1 rise at the same time, the waveform of the input signal INn is rounded by the influence of crosstalk between the two input signals INn and INn−1. In order to suppress the influence of crosstalk, the transmitter TXn changes the signal level of the control signal RISE+ from the “L” level to the “H” level according to the detection result of the signal waveform of the input signals INn and INn−1 at time t20. The transmitter TXn controls the driver strength of the driver circuits 110 and 120 according to the signal level transition of the control signal RISE+. As a result, in the transmitter TXn, the driver strength of the driver circuits 110 and 120 is added.

For example, the operating speed of the signal level transition of the control signal RISE+ is half or less of the response speed of the input signal INn.

Both of the input signals INn and INn−1 have a signal level that rises from the “L” level to the “H” level. Therefore, at time t20, the signal level of the control signals FALL+ and FALL− is maintained at the “L” level.

As a result, at time t20, the influence of crosstalk on the input signal INn (and the input signal INn−1) is suppressed. Therefore, the phase delay of the output signal OUTn is reduced.

At time t21, the signal level of the input signal INn falls from the “H” level to the “L” level. At this time, the signal level of the input signal INn−1 is maintained at the “H” level. For example, the signal level of the control signal RISE+ is maintained at the “H” level, and the signal level of the control signal RISE− is maintained at the “L” level.

Furthermore, at time t21, the signal level of the input signal INn changes from the “H” level to the “L” level, but the signal level of the input signal INn−1 is maintained at the “H” level. Therefore, the signal level of the control signals FALL+ and FALL− is maintained at the “L” level.

At time t30, the signal level of the input signal INn rises from the “L” level to the “H” level. At time t30, the signal level of the input signal INn−1 falls from the “H” level to the “L” level.

At this time, the signal level of the input signal INn changes from the “L” level to the “H” level. Therefore, the signal level of the control signals FALL+ and FALL− is maintained at the “L” level.

In a case where the direction of the signal level transition of the input signal INn−1 is opposite to the direction of the signal level transition of the input signal INn, the waveform of the input signal INn is rounded by the influence of crosstalk between the two input signals INn and INn−1. In order to suppress the influence of crosstalk, the transmitter TXn changes the signal level of the control signal RISE− from the “L” level to the “H” level according to the detection result of the signal waveform of the input signals INn and INn−1 at time t30 in response to the rising of the input signal INn (and the falling of the input signal INn−1). At this time (time t30), the transmitter TXn changes the signal level of the control signal RISE+ from the “H” level to the “L” level. The transmitter TXn controls the driver strength of the driver circuits 110 and 120 according to the signal level transition of the control signal RISE−. As a result, in the transmitter TXn, the driver strength of the driver circuits 110 and 120 is reduced.

As a result, at time t30, the influence of crosstalk on the input signal INn (and the input signal INn−1) is suppressed. Therefore, the phase advance of the output signal OUTn is reduced.

For example, the operating speed of the signal level transition of the control signals RISE+ and RISE− is half or less of the response speed of the input signal INn.

At time t31, the signal level of the input signal INn falls from the “H” level to the “L” level. At time t31, the signal level of the input signal INn−1 is maintained at the “L” level. At this time, for example, the signal level of the control signal RISE− is maintained at the “H” level. The signal level of the control signal RISE+ is maintained at the “L” level.

At time t31, the signal level of the input signal INn changes from the “H” level to the “L” level, but the signal level of the input signal INn−1 is maintained at the “L” level. Therefore, the signal level of the control signals FALL+ and FALL− is maintained at the “L” level.

As described above, in the embodiment, the transmitter TXn of the transmission circuit 11 controls the signal level of the control signals RISE+, RISE−, FALL+, and FALL− to control the driver strength according to the signal transition of the adjacent two input signals INn, and INn−1.

Thus, in the embodiment, the transmitter TXn controls the driver strength of the driver circuits 110 and 120.

As a result, in the transmission circuit 11 of the embodiment, the influence of crosstalk between the transmitters TXn is suppressed.

Furthermore, in the embodiment, the control signals RISE+ and RISE− are signals to be activated in a case where the signal level transition state (signal edge) of the input signal INn on the victim side is a rising edge, and the driver strength of the transmitter TXn on the victim side is changed according to the signal level transition of the input signal INn−1 on the aggressor side. In a case where the control signals RISE+ and RISE− are activated, the signal level of the control signals RISE+ and RISE− is controlled. The control signals FALL+ and FALL− are signals to be activated in a case where the signal level transition state of the input signal INn on the victim side is a falling edge, and the driver strength of the transmitter TXn on the victim side is changed according to the signal level transition of the input signal INn−1 on the aggressor side. In a case where the control signals FALL+ and FALL− are activated, the signal level of the control signals FALL+ and FALL− is controlled.

As described above, the control signals to control the driver strength of the driver, RISE+, RISE−, FALL+, and FALL−, are provided for each signal level transition state of the input signals INn and INn−1 on the adjacent communication paths.

As a result, the operating speed of the signal level transition of the control signals RISE+, RISE−, FALL+, and FALL− can be half or less of the reference, that is, the change speed of the signal level of the input signal INn on the victim side (response speed of the input signal INn).

As a result, in the transmission circuit 11 of the embodiment, the transmitter TXn can relax the restrictions on the timing of the control signals RISE+, RISE−, FALL+, and FALL−.

Furthermore, in the embodiment, the period for the signal level transition of the control signals RISE+, RISE−, FALL+, and FALL− can be shortened, and the activation of the control signals RISE+, RISE−, FALL+, and FALL− is controlled according to the signal level transition state of the input signals INn and INn−1. Therefore, in the transmission circuit 11 of the embodiment, the transmitter TXn can reduce the current generated by the operation to control the control signals RISE+, RISE−, FALL+, and FALL−.

Through a process substantially similar to the control of the driver strength for the rising of the input signal INn illustrated in FIG. 4, for the falling of the input signal INn, the driver strength of the pull-down side of the driver circuits 110 and 120 can be controlled by the control with the control signals according to the signal level transition of the adjacent input signal INn−1, as the control shown in (b) of FIG. 3.

### (c) Specific Example

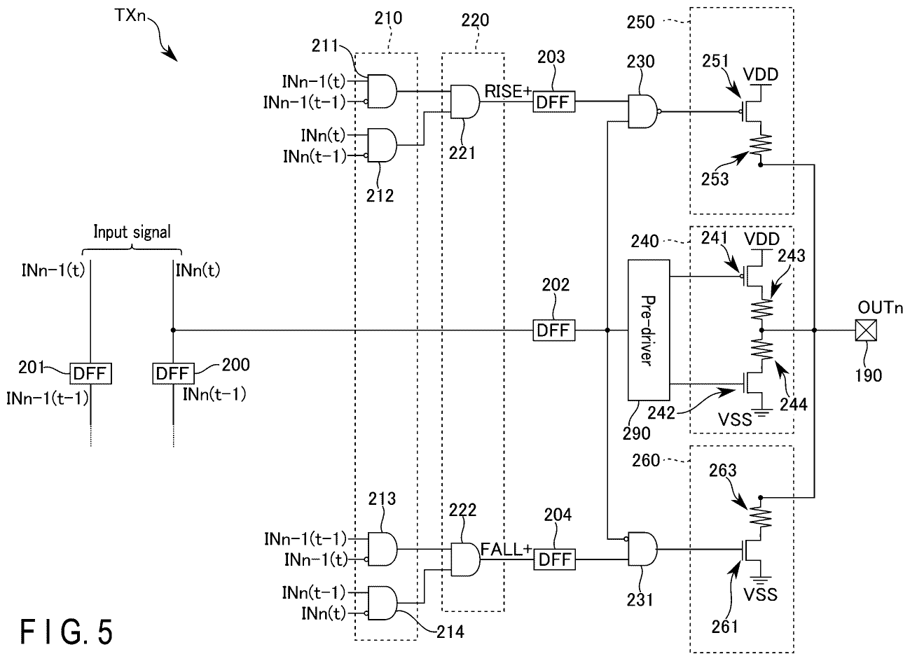

FIG. 5 is a circuit diagram illustrating an example of the specific circuit configuration of the transmitter TXn in the embodiment.

In FIG. 5, the transmitter TXn receives the input signal INn and sends an inverted signal of the input signal INn as the output signal OUTn to the reception circuit 20 via the communication path TP. Note that the example of the transmitter TXn in FIG. 5 illustrates a configuration including components to increase the driver strength but not including components to decrease the driver strength.

The transmitter TXn includes flip-flops 200, 201, 202, 203, and 204, an edge detection unit 210, a signal generation unit 220, a logic gates 230 and 231, and driver units 240, 250, 260, and 290.

In FIG. 5, in the transmitter TXn, the flip-flop 200 receives an input signal INn(t) at the input end of the transmitter TXn, and the flip-flop 201 receives an input signal INn−1(t) at the input end of the transmitter TXn. The flip-flops 200 and 201 holds the received input signals INn(t) and INn−1(t). Upon holding the input signals INn(t) and INn−1(t) at certain time t, the flip-flops 200 and 201 output the temporally one cycle-previous (one clock-previous) signals (hereinafter, also referred to as past signal or holding signal) INn(t−1) and INn−1(t−1). For example, each of the past signals INn(t−1) and INn−1(t−1) is supplied from the flip-flops 200 and 201 to the edge detection unit 210. Each of the flip-flops 200 and 201 is, for example, a D-type flip-flop. The D-type flip-flop is also referred to as DFF.

### <Edge Detection Unit 210>

The edge detection unit 210 detects the change state of the signal waveform of the input signals INn and INn−1 (signal edge). The edge detection unit 210 detects the change state of the signal level of the input signal IN from the “L” level to the “H” level (rising edge) and the change state of the signal level of the input signal IN from the “H” level to the “L” level (falling edge).

In the edge detection unit 210, logic gates 211 and 212 are provided for the pull-up side of the driver units 240, 250, and 260.

The logic gate 211 is an AND gate 211. The AND gate 211 has a positive logic input node and a negative logic input node. The AND gate 211 has an output node connected to the signal generation unit 220. The AND gate 211 receives the input signal INn−1(t) at the positive logic input node. The AND gate 211 receives the signal INn−1(t−1) at the negative logic input node. The AND gate 211 executes a logical product calculation (AND calculation) between the input signal INn−1(t) and an inverted signal of the signal INn−1(t−1). The AND gate 211 outputs the calculation result to the signal generation unit 220.

In a case where the signal level of the input signal INn−1(t) is the “L” level and the signal level of the signal INn−1(t−1) is the “H” level, the AND gate 211 outputs a signal at the “L” level.

In a case where the signal level of the input signal INn−1(t) is the “L” level and the signal level of the signal INn−1(t−1) is the “L” level, the AND gate 211 outputs a signal at the “L” level.

In a case where the signal level of the input signal INn−1(t) is the “H” level and the signal level of the signal INn−1(t−1) is the “H” level, the AND gate 211 outputs a signal at the “L” level.

In a case where the signal level of the input signal INn−1(t) is the “H” level and the signal level of the signal INn−1(t−1) is the “L” level, the AND gate 211 outputs a signal at the “H” level.

As described above, the AND gate 211 on the pull-up side outputs a signal at the “H” level as a calculation result in a case where the signal level of the input signal INn−1 changes from the “L” level to the “H” level.

The logic gate 212 is an AND gate 212. The AND gate 212 has a positive logic input node and a negative logic input node. The AND gate 212 has an output node connected to the signal generation unit 220. The AND gate 212 receives the input signal INn(t) at the positive logic input node. The AND gate 212 receives the signal INn(t−1) at the negative logic input node. The AND gate 212 executes an AND calculation between the input signal INn(t) and an inverted signal of the signal INn(t−1). The AND gate 212 outputs the calculation result to the signal generation unit 220.

In a case where the signal level of the input signal INn(t) is the “L” level and the signal level of the signal INn(t−1) is the “H” level, the AND gate 212 outputs a signal at the “L” level.

In a case where the signal level of the input signal INn(t) is the “L” level and the signal level of the signal INn(t−1) is the “L” level, the AND gate 212 outputs a signal at the “L” level.

In a case where the signal level of the input signal INn(t) is the “H” level and the signal level of the signal INn(t−1) is the “H” level, the AND gate 212 outputs a signal at the “L” level.

In a case where the signal level of the input signal INn(t) is the “H” level and the signal level of the signal INn(t−1) is the “L” level, the AND gate 212 outputs a signal at the “H” level.

As described above, the AND gate 212 on the pull-up side outputs a signal at the “H” level as a calculation result in a case where the signal level of the input signal INn changes from the “L” level to the “H” level. In the edge detection unit 210, logic gates 213 and 214 are provided for the pull-down side of the driver units 240, 250, and 260.

The logic gate 213 is an AND gate 213. The AND gate 213 has a positive logic input node and a negative logic input node. The AND gate 213 has an output node connected to the signal generation unit 220. The AND gate 213 receives the signal INn−1(t−1) at the positive logic input node. The AND gate 213 receives the input signal INn−1(t) at the negative logic input node. The AND gate 213 executes a logical product calculation (AND calculation) between the signal INn−1(t−1) and an inverted signal of the input signal INn−1(t). The AND gate 213 outputs the calculation result to the signal generation unit 220.

In a case where the signal level of the input signal INn−1(t) is the “H” level and the signal level of the signal INn−1(t−1) is the “L” level, the AND gate 213 outputs a signal at the “L” level.

In a case where the signal level of the input signal INn−1(t) is the “H” level and the signal level of the signal INn−1(t−1) is the “H” level, the AND gate 213 outputs a signal at the “L” level.

In a case where the signal level of the input signal INn−1(t) is the “L” level and the signal level of the signal INn−1(t−1) is the “L” level, the AND gate 213 outputs a signal at the “L” level.

In a case where the signal level of the input signal INn−1(t) is the “L” level and the signal level of the signal INn−1(t−1) is the “H” level, the AND gate 213 outputs a signal at the “H” level.

As described above, the AND gate 213 on the pull-down side outputs a signal at the “H” level as a calculation result in a case where the signal level of the input signal INn−1 changes from the “H” level to the “L” level.

The logic gate 214 is an AND gate 214. The AND gate 214 has a positive logic input node and a negative logic input node. The AND gate 214 has an output node connected to the signal generation unit 220. The AND gate 214 receives the signal INn(t−1) at the positive logic input node. The AND gate 214 receives the input signal INn(t) at the negative logic input node. The AND gate 214 executes an AND calculation between the signal INn(t−1) and an inverted signal of the input signal INn(t). The AND gate 214 outputs the calculation result to the signal generation unit 220.

In a case where the signal level of the input signal INn(t) is the “H” level and the signal level of the signal INn(t−1) is the “L” level, the AND gate 214 outputs a signal at the “L” level.

In a case where the signal level of the input signal INn(t) is the “H” level and the signal level of the signal INn(t−1) is the “H” level, the AND gate 214 outputs a signal at the “L” level.

In a case where the signal level of the input signal INn(t) is the “L” level and the signal level of the signal INn(t−1) is the “L” level, the AND gate 214 outputs a signal at the “L” level.

In a case where the signal level of the input signal INn(t) is the “L” level and the signal level of the signal INn(t−1) is the “H” level, the AND gate 214 outputs a signal at the “H” level.

As described above, the AND gate 214 on the pull-down side outputs a signal at the “H” level as a calculation result in a case where the signal level of the input signal INn changes from the “H” level to the “L” level.

### <Signal Generation Unit 220>

The signal generation unit 220 receives a detection result of the signal level transition (signal edge) of the input signals INn and INn−1 from the edge detection unit 210. The signal generation unit 220 generates the control signals RISE+ and FALL+ for an FFE based on the detection result of the signal edge.

The signal generation unit 220 includes two logic gates 221 and 222. The logic gates 221 and 222 are AND gates 221 and 222.

The AND gate 221 has two positive logic input nodes. The AND gate 221 has an output node connected to the flip-flop 203. The AND gate 221 receives the calculation result of the AND gate 211 regarding the detection result of the signal edge of the input signal INn−1 at one input node. The AND gate 221 receives the calculation result of the AND gate 212 regarding the detection result of the signal edge of the input signal INn at the other input node. The AND gate 221 executes an AND calculation between the signal from the AND gate 211 and the signal from the AND gate 212. The AND gate 221 sends the control signal RISE+ corresponding to the result of the AND calculation to the flip-flop 203.

The AND gate 221 outputs the signal RISE+ at the “L” level in a case where at least one of the calculation results of the two AND gates 211 and 212 is at the “L” level. The AND gate 221 outputs the signal RISE+ at the “H” level in a case where both of the calculation results of the two AND gates 211 and 212 are at the “H” level. That is, the AND gate 221 outputs the signal RISE+ at the “H” level in a case where the signal level of both the two input signals INn and INn−1 transits from the “L” level to the “H” level (in a case where the signal edge of both the input signals INn and INn−1 is a rising edge).

The AND gate 222 has two positive logic input nodes. The AND gate 222 has an output node connected to the flip-flop 204. The AND gate 222 receives the calculation result of the AND gate 213 regarding the detection result of the signal edge of the input signal INn−1 at one input node. The AND gate 222 receives the calculation result of the AND gate 214 regarding the detection result of the signal edge of the input signal INn at the other input node. The AND gate 222 executes an AND calculation between the signal from the AND gate 213 and the signal from the AND gate 214. The AND gate 222 sends the control signal FALL+ corresponding to the result of the AND calculation to the flip-flop 204.

The AND gate 222 outputs the signal FALL+ at the “L” level in a case where at least one of the calculation results of the two AND gates 213 and 214 is at the “L” level. The AND gate 222 outputs the signal FALL+ at the “H” level in a case where both of the calculation results of the two AND gates 213 and 214 are at the “H” level. That is, the AND gate 222 outputs the signal FALL+ at the “H” level in a case where the signal level of both the two input signals INn and INn−1 transits from the “H” level to the “L” level (in a case where the signal edge of both the input signals INn and INn−1 is a falling edge).

As described above, the signal generation unit 220 can generate the signals RISE+ and FALL+ to control an FFE according to the state of the signal edge of the two input signals INn and INn−1 in which crosstalk may occur.

### <Flip-Flop 202, 203, and 204>

The flip-flops 202, 203, and 204 are provided for high-speed operation of the transmitter TXn. Each of the flip-flops 202, 203, and 204 is, for example, a D-type flip-flop.

The flip-flop 202 receives the input signal INn(t). The flip-flop 202 temporarily holds the received input signal INn(t). The flip-flop 202 outputs the held input signal INn(t) at a certain timing according to a clock.

The flip-flop 203 receives the signal RISE+ from the AND gate 221 of the signal generation unit 220. The flip-flop 203 temporarily holds the received signal RISE+. The flip-flop 203 outputs the held signal RISE+ at a certain timing according to a clock.

The flip-flop 204 receives the signal FALL+ from the AND gate 222 of the signal generation unit 220. The flip-flop 204 temporarily holds the received signal FALL+. The flip-flop 204 outputs the held signal FALL+ at a certain timing according to a clock.

Note that the flip-flops 202, 203, and 204 are not necessarily provided as long as there is no problem in the input/output timing of the signal in the transmitter TXn.

### <Logic Gate 230 and 231>

The logic gate 230 receives signals from the flip-flops 202 and 203. The logic gate 230 is a NAND gate 230. The NAND gate 230 has two positive logic input nodes. The NAND gate 230 has an output node connected to the driver unit 250. The NAND gate 230 receives the input signal INn(t) from the flip-flop 202 at one input node. The NAND gate 230 receives the signal RISE+ from the flip-flop 203 at the other input node. The NAND gate 230 executes a negative AND calculation (NAND calculation) between the signal INn(t) from the flip-flop 202 and the signal RISE+ from the flip-flop 203. The NAND gate 230 sends a control signal corresponding to the result of the NAND calculation to the driver unit 250.

The NAND gate 230 outputs a control signal at the “H” level in a case where at least one of the signals from the two flip-flops 202 and 203 is at the “L” level. The NAND gate 230 outputs a control signal at the “L” level in a case where both of the signals from the two flip-flops 202 and 203 are at the “H” level.

As described above, the signal RISE+ held in the flip-flop 203 is a signal corresponding to the detection result of the rising edge of the input signals INn and INn−1. Therefore, the signal corresponding to the result of the NAND calculation by the NAND gate 230 indicates a value in which the detection result of the rising edge of the signals INn and INn−1 is reflected to the input signal INn.

Note that the NAND gate 230 may be treated as a part of the signal generation unit 220 or a part of the driver unit 250.

The logic gate 231 receives signals from the flip-flops 202 and 204. The logic gate 231 is an AND gate 231. The AND gate 231 has a positive logic input node and a negative logic input node. The AND gate 231 has an output node connected to the driver unit 260. The AND gate 231 receives the input signal INn(t) from the flip-flop 202 at the negative logic input node. The AND gate 231 receives the signal FALL+ from the flip-flop 204 at the positive logic input node. The AND gate 231 executes an AND calculation between an inverted signal of the signal INn(t) from the flip-flop 202 and the signal FALL+ from the flip-flop 204. The AND gate 231 sends a control signal indicating the calculation result to the driver unit 260.

In a case where the signal INn(t) from the flip-flop 202 is the “L” level and the signal FALL+ from the flip-flop 204 is the “H” level, the AND gate 231 outputs a control signal at the “H” level.

In a case where the signal INn(t) from the flip-flop 202 is the “L” level and the signal FALL+ from the flip-flop 204 is the “L” level, the AND gate 231 outputs a control signal at the “L” level.

In a case where the signal INn(t) from the flip-flop 202 is the “H” level and the signal FALL+ from the flip-flop 204 is the “H” level, the AND gate 231 outputs a control signal at the “L” level.

In a case where the signal INn(t) from the flip-flop 202 is the “H” level and the signal FALL+ from the flip-flop 204 is the “L” level, the AND gate 231 outputs a control signal at the “L” level.

As described above, the signal FALL+ held in the flip-flop 204 is a signal corresponding to the detection result of the falling edge of the input signals INn and INn−1. Therefore, the signal corresponding to the result of the AND calculation by the AND gate 231 indicates a value in which the detection result of the falling edge of the signals INn and INn−1 is reflected to the input signal INn.

Note that the AND gate 231 may be treated as a part of the signal generation unit 220 or a part of the driver unit 260.

### <Driver Unit 240, 250, 260, and 290>

The driver unit 290 is a pre-driver for the driver unit 240. Hereinafter, the driver unit 290 is also referred to as pre-driver 290.

The pre-driver 290 is connected between the flip-flop 202 and the input node of the driver unit 240. The input node of the pre-driver 290 is connected to the output node of the flip-flop 202. The output node of the pre-driver 290 is connected to the input node of the driver unit 240.

The pre-driver 290 outputs an inverted signal of the signal INn(t) from the flip-flop 202 to the driver unit 240.

The driver unit 240 is the main driver of the transmitter TXn. The input node of the driver unit 240 is connected to the output node of the flip-flop 202 holding the input signal INn(t) via the pre-driver 290. The output node of the driver unit 240 is connected to the output terminal 190 of the transmitter TXn.

The driver unit 240 includes a P-type field effect transistor (for example, P-channel MOS transistor) 241, an N-type field effect transistor (for example, N-channel MOS transistor) 242, and resistors 243 and 244. Hereinafter, the field effect transistor is simply referred to as transistor.

One end of the current path of the transistor 241 is connected to the voltage node (hereinafter, referred to as power supply node) to which a voltage VDD is supplied. The other end of the current path of the transistor 241 is connected to one end of the resistor 243. The other end of the resistor 243 is connected to the output node of the driver unit 240. The gate of the transistor 241 is connected to the output node of the pre-driver 290 as the input node of the driver unit 240.

One end of the current path of the transistor 242 is connected to the voltage node (hereinafter, referred to as ground node) to which a voltage VSS is supplied. The other end of the current path of the transistor 242 is connected to one end of the resistor 244. The other end of the resistor 244 is connected to the output node of the driver unit 240. The gate of the transistor 242 is connected to the output node of the pre-driver 290 as the input node of the driver unit 240.

The gate of each transistor 241 and 242 receives an inverted signal of the input signal INn from the pre-driver 290.

The driver unit 240 operates according to the signal level of the input signal INn. In a case where the signal level of the input signal INn is the “L” level, the N-type transistor 242 of the driver unit 240 is driven by the inverted signal of the input signal INn from the pre-driver 290. In this case, the P-type transistor 241 of the driver unit 240 functions as a load. As a result, the driver unit 240 outputs an “L” level signal that is an in-phase signal of the input signal INn. In a case where the signal level of the input signal INn is the “H” level, the P-type transistor 241 of the driver unit 240 is driven by the inverted signal of the input signal INn from the pre-driver 290. In this case, the N-type transistor 242 functions as a load. As a result, the driver unit 240 outputs an “H” level signal that is an in-phase signal of the input signal INn.

The driver unit 250 is a driver (sub-driver) on the pull-up side of the main driver 240. The input node of the driver unit 250 is connected to the output node of the NAND gate 230. The output node of the driver unit 250 is connected to the output terminal 190 of the transmitter TX.

The driver unit 250 includes a P-type transistor 251 and a resistor 253.

One end of the current path of the transistor 251 is connected to the power supply node. The other end of the current path of the transistor 251 is connected to one end of the resistor 253. The other end of the resistor 253 is connected to the output node of the driver unit 250. The gate of the transistor 251 is connected to the output node of the NAND gate 230.

The driver unit 250 operates according to a signal from the NAND gate 230. In a case where the signal level of the signal from the NAND gate 230 is the “L” level, the P-type transistor 251 of the driver unit 250 is driven. As a result, the driver unit 250 outputs a signal at the “H” level. In a case where the signal level of the signal from the NAND gate 230 is the “H” level, the P-type transistor 251 is turned off. As a result, the driver unit 250 enters a non-driving state and is electrically separated from the output terminal 190.

As described above, in a case where both the signal level of the input signal INn and the signal level of the signal from the flip-flop 203 are at the “H” level, the driver unit 250 outputs a signal at the “H” level. On the other hand, in a case where the signal level of the input signal INn is the “L” level, the driver unit 250 is turned off without depending on the signal level of the signal from the flip-flop 203.

Therefore, in a case where the signal level of the input signal INn(t) is the “H” level and the input signals INn and INn−1 both have a rising edge, the output of the driver unit 250 on the pull-up side enhances the output of the driver unit 240. In this manner, the driver units 240 and 250 are driven to enhance the driver strength of the driver units 240 and 250 of the transmitter TX. As a result, the transmitter TX can flow a large current through the output terminal 190.

The driver unit 260 is a driver (sub-driver) on the pull-down side of the main driver 240. The input node of the driver unit 260 is connected to the output node of the AND gate 231. The output node of the driver unit 260 is connected to the output terminal 190 of the transmitter TXn.

The driver unit 260 includes an N-type transistor 261 and a resistor 263.

One end of the current path of the transistor 261 is connected to the ground node. The other end of the current path of the transistor 261 is connected to one end of the resistor 263. The other end of the resistor 263 is connected to the output node of the driver unit 260. The gate of the transistor 261 is connected to the output node of the AND gate 231.

The driver unit 260 operates according to the signal from the AND gate 231. In a case where the signal level of the signal from the AND gate 231 is the “L” level, the N-type transistor 261 of the driver unit 260 is turned off. As a result, the driver unit 260 enters a non-driving state and is electrically separated from the output terminal 190. In a case where the signal level of the signal from the AND gate 231 is the “H” level, the N-type transistor 261 is driven. As a result, the driver unit 260 outputs a signal at the “L” level.

In a case where the signal level of the input signal INn is at the “L” level and the signal level of the signal from the flip-flop 204 is at the “H” level, the driver unit 260 outputs a signal at the “L” level. In a case where the signal level of the input signal INn is at the “H” level or the signal level of the signal from the flip-flop 204 is at the “L” level, the driver unit 260 is turned off.

Therefore, in a case where the signal level of the input signal INn(t) is the “L” level and the input signals INn and INn−1 both have a falling edge, the output of the driver unit 250 on the pull-down side enhances the output of the driver unit 240. In this manner, the driver units 240 and 260 are driven to enhance the driver strength of the driver units 240 and 260 of the transmitter TX. As a result, the transmitter TX can flow a large current through the output terminal 190.

### Operation Example

In the transmission circuit 11 of the embodiment, the transmitter TXn in FIG. 5 operates as follows.

In FIG. 5, the transmitter TXn receives the input signals INn and INn−1.

In the transmitter TXn, the edge detection unit 210 detects the change state of the signal waveforms of the input signals INn and INn−1 (rising edge or falling edge). The signal generation unit 220 generates the control signals RISE+ and FALL+ based on the detection result of the signal edge of the edge detection unit 210.

In the transmitter TXn having the circuit configuration of FIG. 5, in a case where the signal level of the input signal INn is the “H” level, the control signal RISE+ is the “H” level, and the control signal FALL+ is the “L” level (in a case where the signal edge of both the 2-bit input signals INn and INn−1 is a rising edge), the driver unit (main driver) 240 outputs a signal at the “H” level, and the driver unit (sub-driver on the pull-up side) 250 outputs a signal at the “H” level. At this time, the driver unit (sub-driver at the pull-down side) 260 is turned off. As a result, the output signal OUTn from the transmitter TXn is output in a state in which the delay of the signal caused by jitter is suppressed.

In the transmitter TXn having the circuit configuration of FIG. 5, in a case where the signal level of the input signal INn is the “L” level, the control signal RISE+ is the “L” level, and the control signal FALL+ is the “H” level (in a case where the signal edge of both the 2-bit input signals INn and INn−1 is a falling edge), the driver unit (main driver) 240 outputs a signal at the “L” level, and the driver unit (sub-driver on the pull-down side) 260 outputs a signal at the “L” level. At this time, the driver unit (sub-driver on the pull-up side) 250 is turned off. As a result, the output signal OUTn from the transmitter TXn is output in a state in which the delay of the signal caused by jitter is suppressed.

### (d) Summary

In an interface circuit that performs parallel communication, crosstalk occurs between parallel communication paths. Due to the influence of crosstalk such as jitter, transferred signals may degrade.

In the embodiment, the transmission circuit 11 controls the driver strength of the driver unit of the transmitter TXn according to the state of a plurality of signals transferred from each of a plurality of adjacent communication paths. As a result, in the embodiment, the output timing (response speed) of the output signal OUTn of the transmission circuit 11 is controlled. As a result, the transmission circuit 11 of the embodiment can suppress the influence of crosstalk.

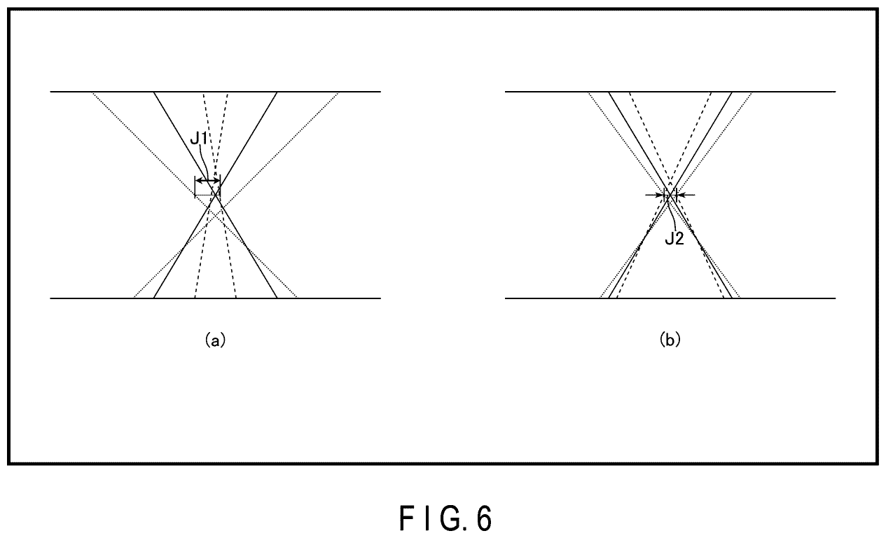

FIG. 6 is a diagram for illustrating the characteristics of the transmission circuit 11 according to the embodiment.

(a) of FIG. 6 illustrates the waveform of a signal output from a general transmission circuit. (b) of FIG. 6 illustrates the waveform of a signal output from the transmission circuit 11 of the embodiment.

As illustrated in (a) of FIG. 6, in a general transmission circuit, the difference between the phase of the signal delayed by jitter and the phase of the signal advanced by the same is indicated by “J1”.

As illustrated in (b) of FIG. 6, in the transmission circuit 11 of the embodiment, the difference between the phase of the signal delayed by jitter and the phase of the signal advanced by the same is indicated by “J2”. The difference J2 is smaller than the difference J1.

As described above, the transmission circuit 11 of the embodiment can reduce the influence of jitter by controlling the driver strength of the driver unit according to the state of a plurality of signals INn and INn−1 whose communication paths are adjacent to each other.

As described above, the transmission circuit as the semiconductor circuit of the embodiment can improve the characteristics.

### (2) Second Embodiment

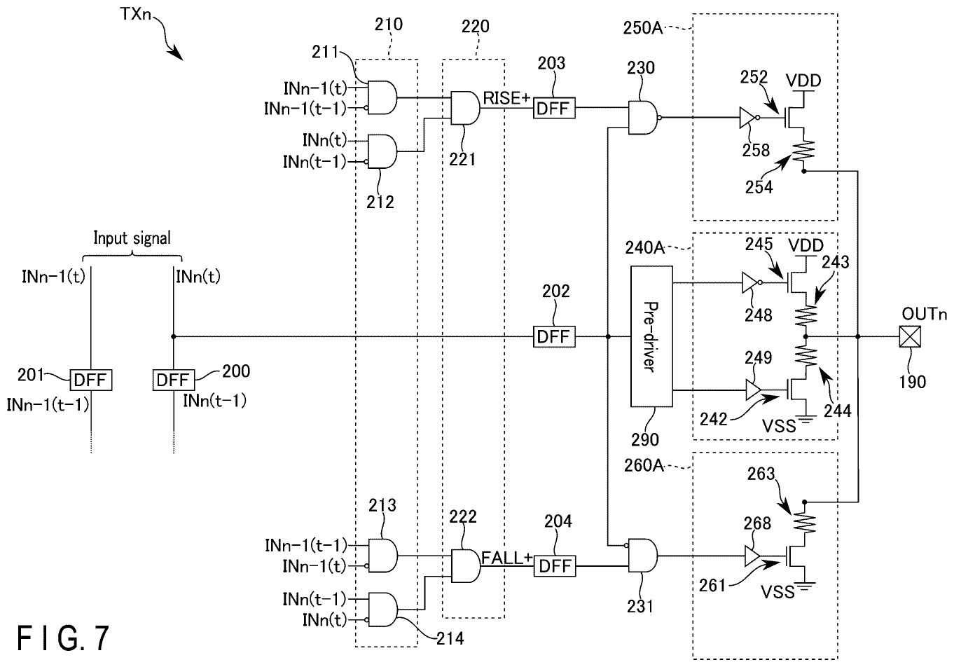

The semiconductor circuit according to the second embodiment will be described with reference to FIG. 7.

FIG. 7 is a circuit diagram illustrating a configuration example of the transmission circuit as the semiconductor circuit of the embodiment.

As illustrated in FIG. 7, in the transmission circuit 11 of the embodiment, the driver units 240A, 250A, and 260A of the transmitter TXn include N-type transistors without using P-type transistors.

The driver unit 240A includes two N-type transistors 242 and 245, resistors 243 and 244, an inverter 248, and a buffer 249. The transistor 245 is, for example, an N-type field effect transistor (for example, N-channel MOS transistor).

One end of the current path of the transistor 245 is connected to the power supply node. The other end of the current path of the transistor 245 is connected to one end of the resistor 243.

The input node of the inverter 248 is connected to the output node of the pre-driver 290. The output node of the inverter 248 is connected to the gate of the transistor 245.

The input node of the buffer 249 is connected to the output node of the pre-driver 290. The output node of the buffer 249 is connected to the gate of the transistor 242.

The signal (an inverted signal of the input signal INn) from the pre-driver 290 is supplied to the input node of the inverter 248 and the input node of the buffer 249. The inverter 248 supplies an in-phase signal of the signal from the flip-flop 202 to the gate of the transistor 245. The buffer 249 supplies an inverted signal of the signal from the flip-flop 202 to the gate of the transistor 242 at a timing corresponding to the output timing of the signal from the inverter 248.

As a result, the driver unit 240A including the two N-type transistors 242 and 245 outputs the input signal INn.

The driver unit 250A includes a transistor 252, a resistor 254, and an inverter 258. The transistor 252 is, for example, an N-type field effect transistor (for example, N-channel MOS transistor).

One end of the current path of the transistor 252 is connected to the power supply node. The other end of the current path of the transistor 252 is connected to one end of the resistor 254. The other end of the resistor 254 is connected to the output node of the driver unit 250A.

The input node of the inverter 258 is connected to the output node of the NAND gate 230. The output node of the inverter 258 is connected to the gate of the transistor 252.

The signal from the NAND gate 230 is supplied to the input node of the inverter 258. The inverter 258 supplies an inverted signal of the signal from the NAND gate 230 to the gate of the transistor 252.

As a result, the driver unit 250A, including the N-type transistor 252, operates according to the inverted signal of the signal from the NAND gate 230.

The driver unit 260A includes an N-type transistor 261, a resistor 263, and a buffer 268.

The input node of the buffer 268 is connected to the output node of the AND gate 231. The output node of the buffer 268 is connected to the gate of the transistor 261.

The signal from the AND gate 231 is supplied to the input node of the buffer 268. The buffer 268 supplies the signal from the AND gate 231 to the gate of the transistor 261.

As a result, the driver unit 260A, including the N-type transistor 261, operates according to the signal from the AND gate 231.

Even in a case where each of the driver units 240A, 250A, and 260A of the transmitter TXn includes only N-type transistor as in the embodiment, the transmitter TXn of the transmission circuit 11 can control the driver strength of the driver according to the signal state of the two supplied input signals INn and INn−1.

Therefore, the transmission circuit 11 as the semiconductor circuit of the second embodiment can obtain substantially the same effects as those of the first embodiment.

### (3) Third Embodiment

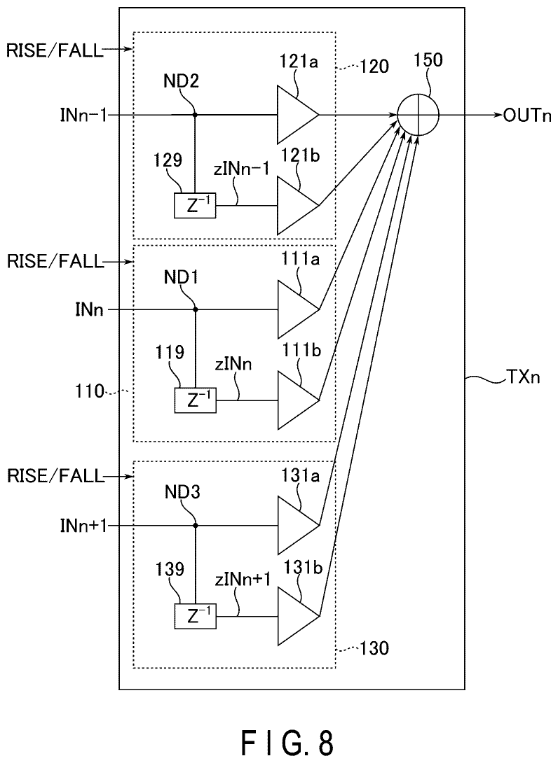

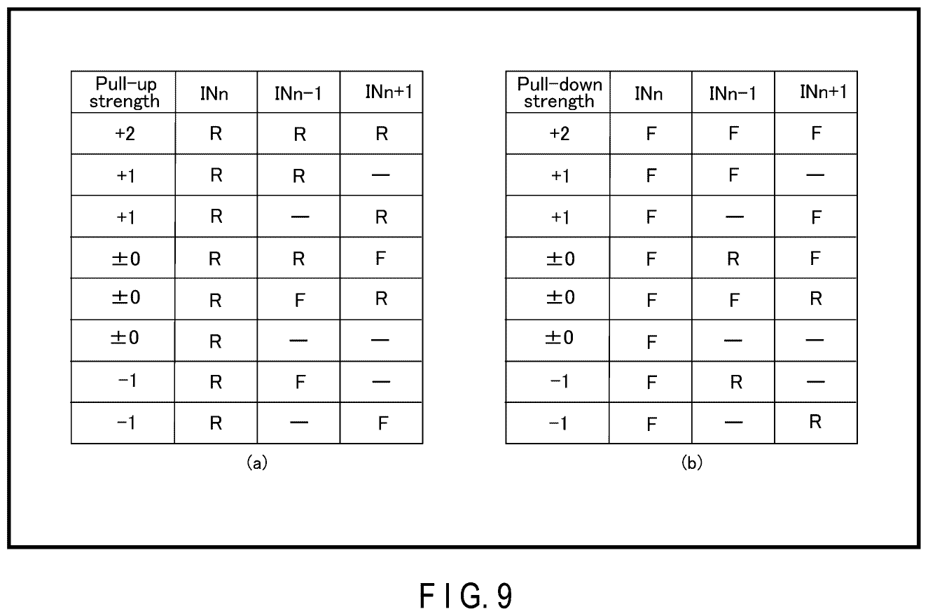

The semiconductor circuit according to the third embodiment will be described with reference to FIGS. 8 and 9.

FIG. 8 is a diagram illustrating the outline of the transmission circuit 11 as the semiconductor circuit according to the embodiment.

As illustrated in FIG. 8, the transmission circuit 11 may be a transmitter including an FFE using 3-bit input signals INn, INn−1, and INn+1. The communication path corresponding to the input signal INn is provided between the communication path corresponding to the input signal INn−1 and the communication path corresponding to the input signal INn+1.

In FIG. 8, the transmitter TXn includes a driver constituted by an FFE at the transmit end of the high-speed interface. As illustrated in FIG. 8, the transmitter TXn includes three driver circuits 110, 120, and 130, and an adder 150.

The driver circuit 130 includes two driver units 131a and 131b and a delay element (conversion filter) 139.

The input node of the driver unit 131a is connected to a node ND3. The input node of the driver unit 131a receives the input signal INn+1 from the preceding circuit. The output node of the driver unit 131a is connected to the adder 150. The driver unit 131a sends the input signal INn+1 to the adder 150. The driver unit 131a performs various processes such as amplification, attenuation, or inversion on the input signal INn+1.

The input node of the delay element 139 is connected to the node ND3. The input node of the delay element 139 receives the input signal INn+1 from the preceding circuit. The output node of the delay element 139 is connected to the input node of the driver unit 131b. The delay element 139 delays the input signal INn−1. The delay element 139 sends the delayed input signal zINn+1 to the driver unit 131b. The delay element 139 forms a separated path for the signal path of the input signal INn+1.

The driver unit 131b is provided between the delay element 139 and the adder 150 on the separated path. The input node of the driver unit 131b is connected to the delay element 139. The input node of the driver unit 131b receives the delayed input signal zINn+1 from the delay element 139. The output node of the driver unit 131b is connected to the adder 150. The driver unit 131b sends the delayed input signal (delay signal) zINn+1 to the adder 150. The driver unit 131b performs various processes such as amplification, attenuation, or inversion on the input signal zINn+1.

The adder 150 executes addition processing of the received six signals INn, zINn, INn−1, zINn−1, INn+1, and zINn+1.

The transmitter TXn acquires an output signal OUTn by using the 3-bit signals INn, INn−1, and INn+1. The transmitter TXn receives the input signal INn to be transmitted (to be processed) and the input signals INn−1 and INn+1 on the two communication paths TP on both sides. The transmitter TXn sends the output signal OUTn obtained by the process in consideration of the signal state of the three input signals INn, INn−1, and INn+1 (for example, signal edge) to the reception circuit 20 via the communication path TP.

FIG. 9 is a diagram illustrating an example of the setting of the driver strength of the transmitter TXn in the transmission circuit 11 according to the embodiment.

(a) of FIG. 9 illustrates a setting example of the driver strength on the pull-up side of the driver unit of the transmitter TXn. (b) of FIG. 9 illustrates a setting example of the driver strength on the pull-down side of the driver unit of the transmitter TXn. In (a) and (b) of FIG. 9, “R” indicates that the signal waveform is in a rising state, and “F” indicates that the signal waveform is in a falling state.

As described above, in a case where the signal waveform of the signal INn on the victim side and the signal waveform of the signals INn−1 and INn+1 on the aggressor side are in the same state, the output timing of the output signal OUTn is delayed due to the influence of crosstalk. The transmitter TXn increases the on-resistance (driver strength) of the driver in order to suppress the timing delay. As a result, the output timing of the output signal OUTn is advanced.

As illustrated in (a) and (b) of FIG. 9, in a case where the signal waveform of the signal INn on the victim side and one or more of the two signals INn−1 and INn+1 on the aggressor side are in the same state, including no signal edge in a different signal waveform state, the transmitter TXn increases the on-resistance of the driver according to the number of the same waveform state.

Note that, in a case where the mutual inductance of the aggressor is large, the strength of the on-resistance is set to be strong, so that the influence of crosstalk (for example, jitter) is reduced.

In a case where the signal waveform of the signal INn on the victim side and the signal waveform of the signals INn−1 and INn+1 on the aggressor side are in a different state, the signal waveform of the signal INn including no signal edge in the same state as the signal waveform of the signals INn−1 and INn+1 on the aggressor side, the output timing of the output signal OUTn is advanced due to the influence of crosstalk. In this case, the transmitter TXn weakens the on-resistance. As a result, the output timing of the output signal OUTn is delayed toward a predetermined timing.

In a case where the signal waveform of the two signals INn−1 and INn+1 on the aggressor side does not change, the transmitter TXn is set to a driver strength of “0” without changing the on-resistance, assuming that there is no influence of crosstalk between the signals INn, INn−1, and INn+1.

In a case where the signal waveform of the signal INn−1 on one aggressor side is different from the signal waveform of the signal INn+1 on the other aggressor side, the transmitter sets the driver strength according to the number of states of the signals INn−1 and INn+1 on the aggressor side with respect to the state of the signal waveform of the signal INn on the victim side as in the following equation (f1). Here, the number of aggressors having a signal edge in the same state as the signal edge of the victim is denoted as “N1”, and the number of aggressors having a signal edge in a state different from the signal edge of the victim is denoted as “N2”.

Driver strength=N1−N2 (f1)

For example, in a case where there is a difference in magnitude among the mutual inductances between the communication path of the victim and the communication path of each of the aggressors, the driver strength is determined by using coefficients set for each of the aggressors, as in the following equation (f2). Here, among the signals INn−1 and INn+1 on the two aggressor sides each adjacent to the victim, the coefficient set for the signal INn−1 on one aggressor side is denoted as “a”, and the coefficient set for the signal INn+1 on the other aggressor side is denoted as “b”. The number of signals INn−1 on one aggressor side having the same signal waveform as that of the signal INn on the victim is denoted as N1p, and the number of signals INn+1 on the other aggressor side having the same signal waveform as that of the signal INn on the victim is denoted as N1q. The number of signals INn−1 on one aggressor side having a signal waveform different from that of the signal INn on the victim is denoted as N2p, and the number of signals INn+1 on the other aggressor side having a signal waveform different from that of the signal INn on the victim is denoted as N2q.

Driver strength=a×N1p+b×N1q−a×N2p−b×N2q (f2)

In a case where the number of aggressors is two or more for the victim, the magnitude of the coefficient according to mutual inductance may be set to a different magnitude for each of the aggressors.

Note that the embodiment illustrates an example in which the driver strength of the transmitter on the victim is increased or decreased according to the signal waveform on the aggressor side. However, in a case where it is difficult to mount a configuration for reducing the driver strength depending on the circuit configuration of the transmission circuit, the transmission circuit may control the driver strength only with a configuration for increasing the driver strength. Also in this case, the transmission circuit of the embodiment can mitigate the influence of crosstalk such as jitter.

In the transmission circuit 11 of the embodiment, the number of the input signals IN supplied to the transmitter TXn may be 4 or more.

Therefore, the transmission circuit as the semiconductor circuit of the third embodiment can obtain substantially the same effects as those of the above embodiments.

### (4) Fourth Embodiment

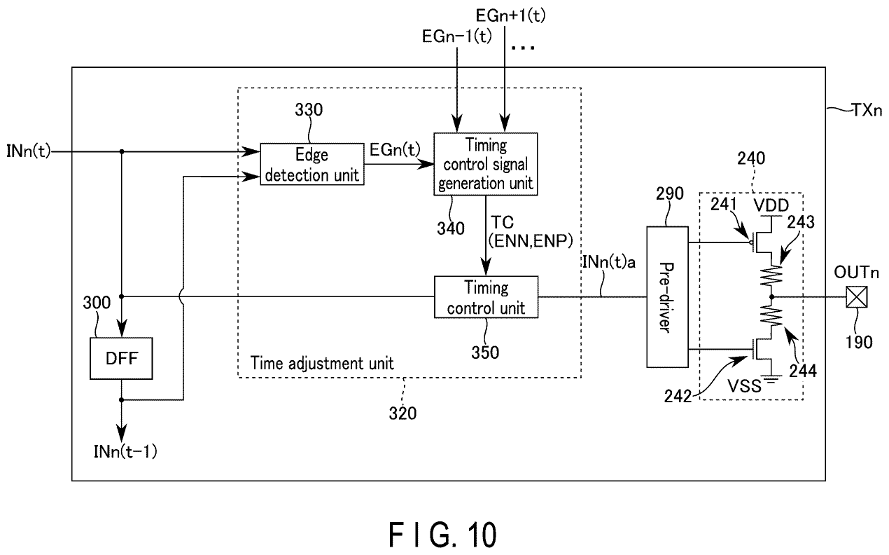

The semiconductor circuit according to the fourth embodiment will be described with reference to FIGS. 10 to 15.

### (a) Circuit Example

FIG. 10 is a circuit diagram illustrating the circuit configuration of the transmission circuit 11 as the semiconductor circuit of the embodiment. The transmission circuit 11 of the embodiment reduces the influence of crosstalk by using a time adjustment unit 320 capable of controlling the time for signal transfer.

As illustrated in FIG. 10, in the transmission circuit 11 of the embodiment, the transmitter TXn includes a flip-flop 300, a time adjustment unit 320, and driver units 240 and 290. The time adjustment unit 320 includes, for example, an edge detection unit 330, a timing control signal generation unit 340, and a timing control unit 350.

The flip-flop 300 holds the input signal INn supplied to the transmitter TXn in a certain period (for example, a period corresponding to one clock). The flip-flop 300 outputs the held signal as the past signal INn(t−1).

The edge detection unit 330 detects the signal edge of the input signal INn(t). The edge detection unit 330 outputs an edge detection signal EGn(t) according to the detection result. For example, the edge detection unit 330 detects whether the signal waveform of the input signal INn(t) is a rising edge or a falling edge by using the input signal INn(t) and the past signal INn(t−1). Note that the signal edge is not necessarily detected for an input signal IN that does not affect jitter due to crosstalk.

The timing control signal generation unit 340 generates a control signal TC to control the transmission timing (for example, the delay time) of the input signal. For example, at a certain time t, the timing control signal generation unit 340 receives the edge detection signal EGn(t) of the corresponding input signal INn(t) and the edge detection signals EGn−1(t) and EGn+1(t) of other several bits of input signals (for example, 2-bit input signals) INn−1 and INn+1. The timing control signal generation unit 340 generates the control signal TC by using the edge detection signals EGn(t), EGn−1(t), and EGn+1(t). The magnitude of the delay time indicated by the control signal TC is set according to, as illustrated in FIGS. 3 and 9, the relationship between the signal waveform state of the input signal INn and the signal waveform state of the adjacent input signals INn−1 and INn+1; and the number of rising edge and falling edge of the signal waveform of the adjacent input signals INn−1 and INn+1.

The timing control unit 350 adjusts the transmission timing of the input signal INn(t) (delay time of the signal INn(t)) based on the control signal TC. The timing control unit 350 outputs an input signal INn(t) a to the driver unit 240 at a timing corresponding to the delay time indicated by the control signal TC. For example, the timing control unit 350 includes a time adjustment buffer.

The driver unit 290 is connected between the timing control unit 350 and the driver unit 240. The driver unit 290 is a pre-driver 290 for the driver unit 240. The input node of the pre-driver 290 is connected to the output node of the timing control unit 350. The output node of the pre-driver 290 is connected to the input node of the driver unit 240. The pre-driver 290 outputs an inverted signal of the input signal INn(t)a to which a certain delay amount is added by the timing control unit 350 to the driver unit 240.

The driver unit (main driver) 240 is connected between the pre-driver 290 and the output terminal 190 of the transmitter TXn. The input node of the driver unit 240 is connected to the output node of the pre-driver 290. The output node of the driver unit 240 is connected to the output terminal 190 of the transmitter TX. The driver unit 240 outputs an in-phase signal of the input signal INn(t)a to which a certain delay amount is added by the timing control unit 350 to the output terminal 190 as the output signal OUTn of the transmitter TXn.

### <Edge Detection Unit 330>

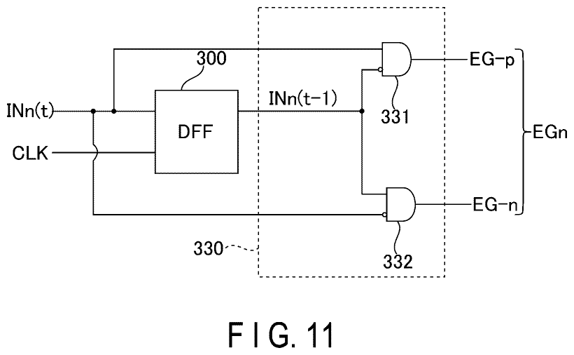

FIG. 11 is a circuit diagram illustrating a configuration example of the edge detection unit 330 of the transmitter TXn in the transmission circuit 11 of the embodiment.

The edge detection unit 330 detects the signal edge of the input signal INn(t) by a logical calculation between the current input signal INn(t) and the past input signal (for example, one clock-previous input signal) INn(t−1).

The edge detection unit 330 includes two logic gates 331 and 332.

The edge detection unit 330 detects the rising edge of the input signal INn at the logic gate 331. The logic gate 331 is an AND gate 331. The AND gate 331 includes a positive logic input node and a negative logic input node.

The AND gate 331 receives the current input signal INn(t) at the positive logic input node. The AND gate 331 receives the one clock-previous input signal INn(t−1) from the flip-flop 300 at the negative logic input node.

In a case where the signal level of the current input signal INn(t) is the “H” level and the signal level of the signal (past signal) INn(t−1) is the “L” level, the AND gate 331 outputs a signal EG-p at the “H” level.

In a case where the signal level of the current input signal INn(t) is the “H” level and the signal level of the signal INn(t−1) is the “H” level, the AND gate 331 outputs a signal EG-p at the “L” level.

In a case where the signal level of the current input signal INn(t) is the “L” level and the signal level of the signal INn(t−1) is the “L” level, the AND gate 331 outputs a signal EG-p at the “L” level.

In a case where the signal level of the current input signal INn(t) is the “L” level and the signal level of the signal INn(t−1) is the “H” level, the AND gate 331 outputs a signal EG-p at the “L” level.

The situation in which the signal level of the past input signal INn(t−1) is the “L” level and the signal level of the current input signal INn(t) is the “H” level indicates that the signal waveform (signal state) of the input signal INn(t) is a rising edge. Therefore, the signal EG-p at the “H” level output from the AND gate 331 indicates that the rising edge of the input signal INn(t) is detected.

The edge detection unit 330 detects the falling edge of the input signal INn at the logic gate 332. The logic gate 332 is an AND gate 332. The AND gate 332 includes a negative logic input node and a positive logic input node.

The AND gate 332 receives the current input signal INn(t) at the negative logic input node. The AND gate 332 receives the one clock-previous input signal INn(t−1) from the flip-flop 300 at the positive logic input node.

In a case where the signal level of the current input signal INn(t) is the “H” level and the signal level of the signal INn(t−1) is the “L” level, the AND gate 332 outputs a signal EG-n at the “L” level.

In a case where the signal level of the current input signal INn(t) is the “H” level and the signal level of the signal INn(t−1) is the “H” level, the AND gate 332 outputs a signal EG-n at the “L” level.

In a case where the signal level of the current input signal INn(t) is the “L” level and the signal level of the signal INn(t−1) is the “L” level, the AND gate 332 outputs a signal EG-n at the “L” level.

In a case where the signal level of the current input signal INn(t) is the “L” level and the signal level of the signal INn(t−1) is the “H” level, the AND gate 332 outputs a signal EG-n at the “H” level.

The situation in which the signal level of the past input signal INn(t−1) is the “H” level and the signal level of the current input signal INn(t) is the “L” level indicates that the signal waveform of the input signal INn(t) is a falling edge. Therefore, the signal at the “H” level output from the AND gate 332 indicates that the falling edge of the input signal INn(t) is detected.

In this manner, the edge detection unit 330 in FIG. 11 can detect the rising edge and the falling edge of the input signal INn(t).

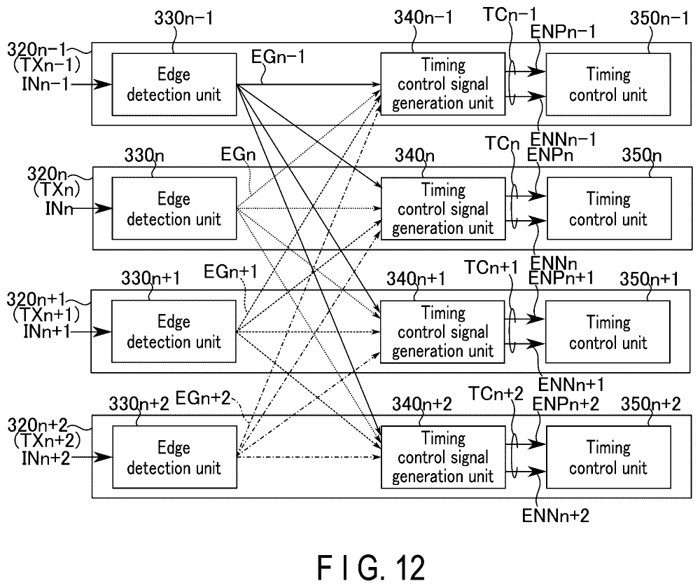

FIG. 12 is a schematic diagram relating to the four communication paths (four input signals INn, INn−1, INn+1, and INn+2), and illustrating the relationship between the edge detection unit 330 (330n, 330n−1, 330n+1, and 330n+2) and the timing control signal generation unit 340 (340n, 340n−1, 340n+1, and 340n+2).

### <Timing Control Signal Generation Unit 340>

The timing control signal generation unit 340 receives an edge detection signal EGn from the corresponding edge detection unit 330 and a plurality of edge detection signals EGn−1, EGn+1, and EGn+2 related to other input signals INn−1(t), INn+1(t), and INn+2(t). The edge detection signals EGn−1, EGn+1, and EGn+2 are supplied from other transmitters TXn−1, TXn+1, and TXn+2. The timing control signal generation unit 340 generates a control signal TC indicating a time adjustment amount (for example, delay amount) to be added to the corresponding input signal INn(t) based on the edge detection signals EGn, EGn−1, EGn+1, and EGn+2.

The timing control signal generation unit 340 supplies the generated control signal TC to the timing control unit (time adjustment buffer) 350. The control signal TC is a signal indicated by several bits of values. For example, the control signal TC includes codes (bit values) ENP and ENN to control the driving force of the timing control unit 350.

The code ENN is a signal that is activated in a case where the transition of the signal level of the input signal INn is a falling edge and the magnitude of the delay amount (driver strength) of the timing control unit 350 is changed. The code ENP is a signal that is activated in a case where the transition of the signal level of the input signal INn is a rising edge and the magnitude of the delay amount of the timing control unit 350 is changed.

In this way, control is performed such that the code ENP corresponds to the rising edge of the input signal INn and the code ENN corresponds to the falling edge of the input signal INn. Therefore, the operating speed to control the codes ENP and ENN is half or less of the response speed of the input signal INn.

In addition, the operation to control the codes ENP and ENN is executed only upon the change of the codes ENP and ENN. Therefore, it is possible to reduce current generated by the operation of the timing control signal generation unit 340.

### <Edge Detection Unit 330>

As illustrated in FIG. 12, in the time adjustment units 320n, 320n−1, 320n+1, and 320n+2 of the transmitters TXn, TXn−1, TXn+1, and TXn+2, each of the edge detection units 330n, 330n−1, 330n+1, and 330n+2 independently detects the rising edge or the falling edge of the received input signals INn, INn−1, INn+1, and INn+2.

Each of the edge detection units 330 outputs the edge detection signal EG (EGn, EGn−1, EGn+1, and EGn+2) corresponding to the signal edge detected from the input signal IN(t) and the past signal IN(t−1).

Each of the edge detection units 330 sends the edge detection signal EG to the corresponding and other timing control signal generation units 340.

For example, the edge detection unit 330n sends the edge detection signal EGn related to the signal edge detected in the input signal INn to the corresponding timing control signal generation unit 340n and other timing control signal generation units 340n−1, 340n+1, and 340n+2.

The edge detection unit 330n−1 sends the edge detection signal EGn−1 related to the signal edge detected in the input signal INn−1 to the corresponding timing control signal generation unit 340n−1 and other timing control signal generation units 340n, 340n+1, and 340n+2.

The edge detection unit 330n+1 sends the edge detection signal EGn+1 related to the signal edge detected in the input signal INn+1 to the corresponding timing control signal generation unit 340n+1 and other timing control signal generation units 340n, 340n−1, and 340n+2.

The edge detection unit 330n+2 sends the edge detection signal EGn+2 related to the signal edge detected in the input signal INn+2 to the corresponding timing control signal generation unit 340n+2 and other timing control signal generation units 340n, 340n−1, and 340n+1.

The timing control signal generation unit 340n sets the codes ENPn and ENNn of the control signal TCn based on the edge detection signals EGn, EGn−1, EGn+1, and EGn+2. The timing control signal generation unit 340n sends the control signal TCn including the codes ENPn and ENNn to the corresponding timing control unit 350n.

The timing control signal generation unit 340n−1 sets the codes ENPn−1 and ENNn−1 of the control signal TCn−1 based on the edge detection signals EGn, EGn−1, EGn+1, and EGn+2. The timing control signal generation unit 340n−1 sends the control signal TCn−1 including the codes ENPn−1 and ENNn−1 to the corresponding timing control unit 350n−1.

The timing control signal generation unit 340n+1 sets the codes ENPn+1 and ENNn+1 of the control signal TCn+1 based on the edge detection signals EGn, EGn−1, EGn+1, and EGn+2. The timing control signal generation unit 340n+1 sends the control signal TCn+1 including the codes ENPn+1 and ENNn+1 to the corresponding timing control unit 350n+1.

The timing control signal generation unit 340n+2 sets the codes ENPn+2 and ENNn+2 of the control signal TCn+2 based on the edge detection signals EGn, EGn−1, EGn+1, and EGn+2. The timing control signal generation unit 340n+2 sends the control signal TCn+2 including the codes ENPn+2 and ENNn+2 to the corresponding timing control unit 350n+2.

As described above, the edge detection unit 330 and the timing control signal generation unit 340 can set the delay amount for the corresponding input signal IN based on the signal state (signal edge) of the corresponding communication path TP and the communication paths TP in the vicinity thereof.

### <Timing Control Unit 350>

The timing control unit 350 receives the input signal INn(t) and the control signal TC. The timing control unit 350 adds a delay amount corresponding to the control signal TC to the input signal INn(t). As a result, the timing control unit 350 outputs the delayed input signal INn(t) a at a timing corresponding to the delay amount of the control signal TC.

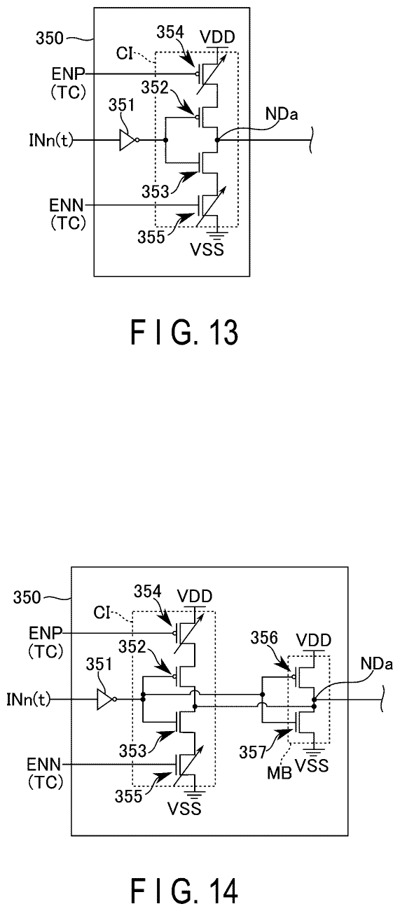

FIG. 13 is a circuit diagram illustrating a configuration example of the timing control unit 350 of the transmitter TXn in the transmission circuit 11 of the embodiment.

As illustrated in FIG. 13, the timing control unit 350 includes an inverter 351, P-type transistors 352 and 354, and N-type transistors 353 and 355.

The input node of the inverter 351 receives the input signal INn(t). The output node of the inverter 351 is connected to the gate of the P-type transistor 352 and the gate of the N-type transistor 353.

Each of the transistors 352, 353, 354, and 355 is an inverter CI having a cascode structure.

One end of the current path of the transistor 352 is connected to an output node NDa of the timing control unit 350. The other end of the current path of the transistor 352 is connected to one end of the current path of the P-type transistor 354. The other end of the current path of the transistor 354 is connected to the power supply node to which a voltage VDD is applied.

One end of the current path of the transistor 353 is connected to the output node NDa of the timing control unit 350. The other end of the current path of the transistor 353 is connected to one end of the current path of the N-type transistor 355. The other end of the current path of the transistor 355 is connected to the ground node to which a voltage VSS is applied.

The gate of the transistor 354 receives the code ENP included in the control signal TC. The transistor 354 operates with a driving force corresponding to the value of the received code ENP. The transistor 354 functions as a load (variable resistance) in the inverter CI having a cascode structure.

The gate of the transistor 355 receives the code ENN included in the control signal TC. The transistor 355 operates with a driving force corresponding to the value of the received code ENN. The transistor 355 functions as a load in the inverter having a cascode structure.

The timing control unit 350 outputs an in-phase signal of the input signal INn (having the same signal level) with a delay amount corresponding to the codes ENP and ENN of the control signal TC.

FIG. 14 is a circuit diagram illustrating another configuration example of the timing control unit 350.

As illustrated in FIG. 14, the timing control unit 350 further includes a P-type transistor 356 and an N-type transistor 357. The transistor 356 and the transistor 357 function as a main buffer (main driver) MB of the timing control unit 350. One end of the current path of the transistor 356 is connected to the output node NDa of the timing control unit 350. The other end of the current path of the transistor 356 is connected to the power supply node. One end of the current path of the transistor 357 is connected to the output node NDa of the timing control unit 350. The other end of the current path of the transistor 357 is connected to the ground node. The gate of the transistor 356 and the gate of the transistor 357 are connected to the output node of the inverter 351.

The main buffer MB is connected between the power supply node and the ground node, being parallel to the inverter CI having a cascode structure. The main buffer MB is an always-on buffer.

In FIG. 14, the timing control unit 350 outputs an in-phase signal of the input signal INn (having the same signal level) with a delay amount corresponding to the codes ENP and ENN of the control signal TC.

### <Setting Example of Control Signal TC>

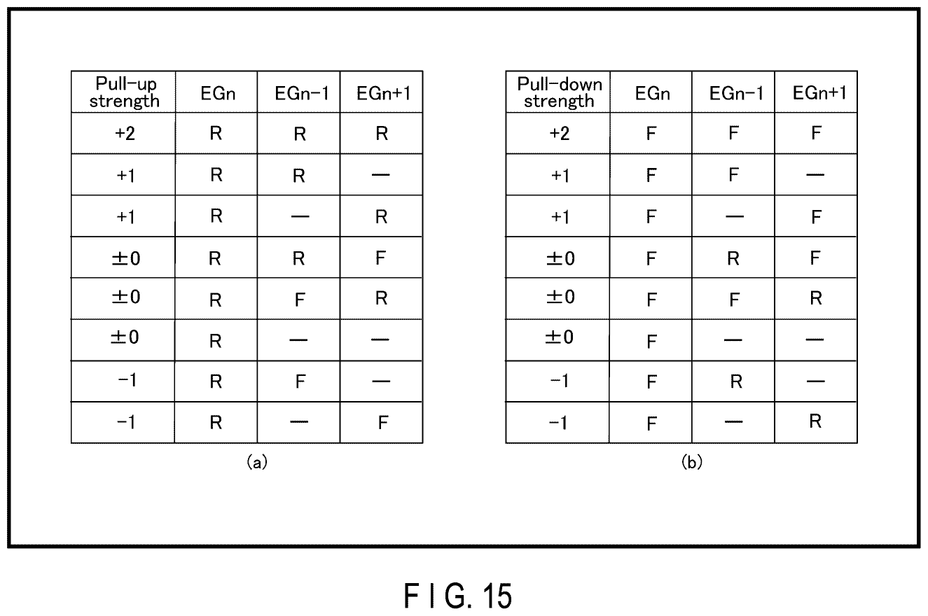

FIG. 15 is a diagram illustrating an example of the setting of the driver strength of the transmitter TXn in the transmission circuit 11 according to the embodiment by the timing control signal generation unit 340. FIG. 15 illustrates a setting example of the driver strength of the timing control unit 350 according to the detection results of the three edge detection signals EGn, EGn−1, and EGn+1. In (a) and (b) of FIG. 15, “R” indicates that the detected signal waveform is in a rising state (rising edge), and “F” indicates that the detected signal waveform is in a falling state (falling edge). In addition, “−” indicates that the detected signal waveform is in a state fixed to the “L” level or the “H” level (non-change state).

(a) of FIG. 15 illustrates a setting example of the driver strength on the pull-up side of the transmitter TXn. (b) of FIG. 15 illustrates a setting example of the driver strength on the pull-down side of the transmitter TXn.

Here, the edge detection signal EGn corresponds to the communication path on the victim (input signal INn), and the edge detection signals EGn−1 and EGn+1 correspond to the communication paths on the aggressor (input signals INn−1 and INn+1).

As illustrated in (a) and (b) of FIG. 15, in a case where the detection result of the edge detection signal EGn on the victim side and the detection results of the edge detection signals EGn−1 and EGn+1 on the aggressor side are in the same state, the input signals INn, INn−1, and INn+1 operate in the same signal edge state, which means that the output signal OUTn has a delayed output timing due to the influence of crosstalk. In the transmitter TXn, the driver strength indicated by the value of the codes ENP and ENN is set to a value as large as +2 in order to suppress timing delay. As a result, the driver strength (on-resistance) of the timing control unit 350 is increased. As a result, the output timing of the output signal OUTn is advanced.

In a case where the detection result of the edge detection signal EGn on the victim side is the same as one or more detection results of the two edge detection signals EGn−1 and EGn+1 on the aggressor side, the transmitter TXn increases the driver strength of the timing control unit 350 according to the number of the same detection result.

Note that, in a case where the mutual inductance of the aggressor is large, the strength of the on-resistance is set to be strong, so that the influence of crosstalk (for example, jitter) is reduced.

In a case where the detection result of the edge detection signal EGn on the victim side is different from the detection results of all the signals EGn−1 and EGn+1 on the aggressor side, the input signals INn, INn−1, and INn+1 operate in different signal edge states, which means that the output signal OUTn has an advanced output timing due to the influence of crosstalk. In this event, in the transmitter TXn, the driver strength is set to a value as small as −1 in order to suppress advanced timing. As a result, the driver strength of the timing control unit 350 is decreased. As a result, the output timing of the output signal OUTn is delayed.

In a case where the detection results of the edge detection signals EGn−1 and EGn+1 on the aggressor side do not change, the transmitter TXn is set to a driver strength value of 0 (zero) without changing the driver strength of the timing control unit 350, assuming that there is no influence of crosstalk between the input signals INn, INn−1, and INn+1.

In a case where the detection result of the edge detection signal EGn−1 on an aggressor side is different from the detection result of the edge detection signal EGn+1 on another aggressor side, the transmitter TXn can set the driver strength according to the detection results of the edge detection signals EGn−1 and EGn+1 on the aggressor side with respect to the detection result of the edge detection signal EGn on the victim side, in the same manner as in the above equation (f1).

In addition, in a case where there is a difference in magnitude among the mutual inductances between the communication path of the victim and the communication path of each of the aggressors, the driver strength of the timing control unit 350 may be determined by using coefficients set for each of the aggressors, in the same manner as in the above equation (f2).

### (b) Operation Example

Hereinafter, an operation example of the transmitter TXn including the time adjustment unit 320 in the transmission circuit 11 of the embodiment will be described.

In the transmitter TXn in FIG. 10, the input signal INn(t) is supplied to the transmitter TXn at time t. The transmitter TXn receives the input signal INn(t).

The edge detection unit 330 receives the input signal INn(t) and the past input signal INn(t−1) from the flip-flop 300. The edge detection unit 330 detects the state of the signal edge of the input signal INn(t) based on the input signal INn(t) and the input signal INn(t−1). The edge detection unit 330 sends the edge detection signal EGn corresponding to the input signal INn to the timing control signal generation unit 340.

The timing control signal generation unit 340 receives the edge detection signal EGn and the edge detection signals EG (EGn−1, EGn+1, . . . ) from other transmitters TX. The timing control signal generation unit 340 generates the timing control signal TC including the codes ENP and ENN based on the edge detection signals EG. The timing control signal generation unit 340 sends the generated timing control signal TC to the timing control unit 350.

The timing control unit 350 receives the input signal INn and the timing control signal TC. The timing control unit 350 operates by a driving force (operating speed) corresponding to the codes ENP and ENN of the timing control signal TC.

As a result, the input signal INn is sent to the driver unit 240 in a state where a delay amount corresponding to the driving force of the timing control unit 350 is included. Note that no delay amount may be added to the input signal INn depending on the state of the edge detection signals EG.

The driver unit 240 receives the input signal INn from the timing control unit 350, from the timing control unit 350 that operated according to the timing control signal TC. The driver unit 240 outputs a signal corresponding to the input signal INn (for example, an inverted signal of the input signal INn) as the output signal OUTn.

As described above, in the transmission circuit 11 of the embodiment, the transmitter TX outputs the output signal OUT corresponding to the input signal IN.

### (c) Summary

The transmission circuit 11 of the embodiment adds a delay amount to the corresponding input signal INn depending on the signal state of other adjacent input signals INn−1 and INn+1. As a result, in the embodiment, the output timing of the output signal OUTn according to the signal INn is adjusted. As a result, the transmission circuit 11 of the embodiment can suppress the influence of crosstalk.

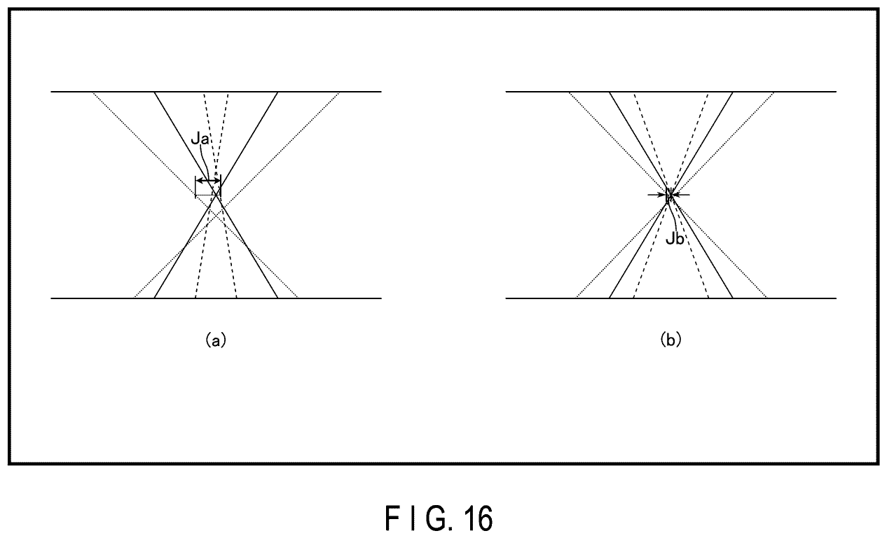

FIG. 16 is a diagram for illustrating the effects of the transmission circuit 11 according to the embodiment.

(a) of FIG. 16 illustrates the waveform of a signal output from a general transmission circuit. (b) of FIG. 16 illustrates the waveform of a signal output from the transmission circuit 11 of the embodiment.

As illustrated in (a) of FIG. 16, in a general transmission circuit, the difference between the phase of the signal delayed by jitter and the phase of the signal advanced by the same is indicated by “Ja”. As illustrated in (b) of FIG. 16, in the transmission circuit 11 of the embodiment, the difference between the phase of the signal delayed by jitter and the phase of the signal advanced by the same is indicated by “Jb”. The difference Jb is smaller than the difference Ja.

As described above, the transmission circuit 11 of the embodiment is capable of reducing the influence of crosstalk such as jitter by adjusting the output timing of the output signal OUTn according to the input signal INn depending on the state of the signals INn and INn−1 whose communication paths are adjacent to each other.

As described above, the transmission circuit as the semiconductor circuit of the embodiment can improve the characteristics.

### (5) Application Example

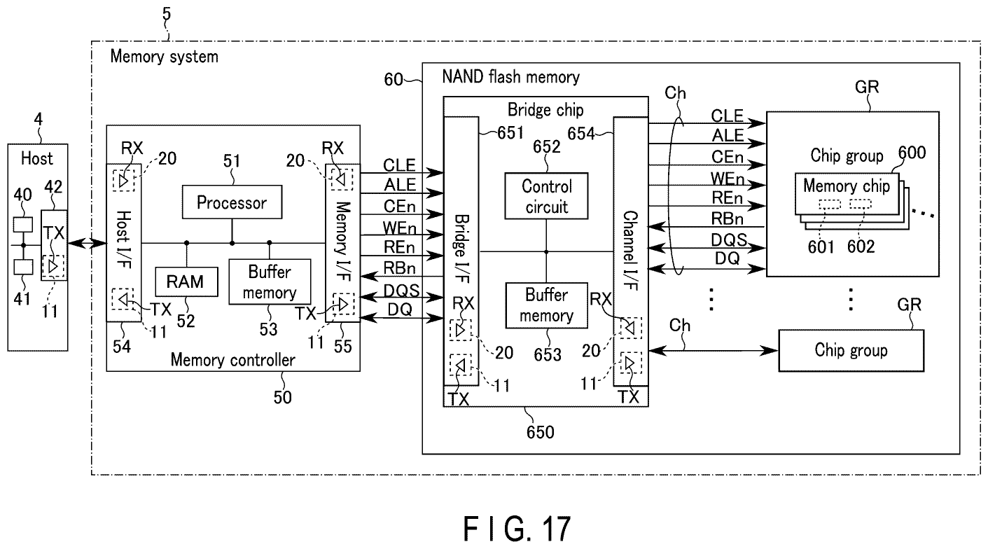

Application examples of the semiconductor circuit according to the embodiment will be described with reference to FIG. 17.

The transmission circuit 11 as the semiconductor circuit of the embodiment is applied to, for example, the interface circuit of a memory system.

As illustrated in FIG. 17, an information communication system includes a host 4 and a memory system 5. The memory system 5 writes data, reads data, and erases data in the memory system 5 based on a request from the host 4. The internal configuration of the memory system 5 will be described later.

The host 4 can generate a command (hereinafter, referred to as host command) to request various processes and operations for the memory system 5. The host 4 can generate data according to the host command. The generated data is information (for example, address) used for process and operation of the memory system 5, parameters, data to be written in the memory system 5, and the like.

The host 4 includes a processor 40, a RAM 41, an interface circuit 42, and the like. The host 4 may further include a storage device (not illustrated) such as a hard disc drive (HDD).

For example, the host 4 is a personal computer, a smartphone, a feature phone, a mobile terminal (for example, a tablet terminal), a game device, an in-vehicle terminal, a router, a base station, or the like.

The memory system 5 includes a memory controller 50 and a NAND flash memory (memory device) 60. For example, the memory system 5 is a solid state drive (SSD), a universal flash storage (UFS) device, a memory card, a universal serial bus (USB) memory, or the like. Instead of the NAND flash memory 60, another nonvolatile or volatile memory device may be used for the memory system 5.

The memory controller 50 orders the NAND flash memory 60 to perform various processes and operations such as writing of data, reading of data, and erasing of data based on a request from the host 4.

The memory controller 50 includes a processor 51, a RAM 52, a buffer memory 53, and interface circuits 54 and 55.

The processor 51 can order various processes or operations on the NAND flash memory 60. For example, the processor 51 can generate a command (hereinafter, also referred to as controller command) to the NAND flash memory 60.

The RAM 52 functions as a work area for various processes and operations of the processor 51 in the memory controller 50. The RAM 52 temporarily stores programs, data to be used for various processes by the processor 51 (results of calculation processing, data and parameters in the middle of calculation processing), and the like. Note that the RAM 52 may be a memory area provided in the processor 51.

The buffer memory 53 temporarily stores data transferred between the memory controller 50 and the host 4 and data transferred between the memory controller 50 and the NAND flash memory 60.

The interface circuit (also referred to as host interface (host I/F) circuit) 54 performs communication (data transfer) between the host 4 and the memory controller 50 based on an interface standard. The interface standard (and communication protocol) of the interface circuit 54 is the same standard (or compliant standard) as the interface standard of the interface circuit of the host 4.

The interface circuit (also referred to as memory interface (memory I/F) circuit) 55 performs communication between the memory controller 50 and the NAND flash memory 60 based on the NAND interface standard. The interface circuit 55 performs, for example, parallel transmission communication (parallel communication) with the NAND flash memory 60. The interface circuit 55 includes a transmission circuit 11 and a reception circuit 20 in a physical layer (PHY layer).

In a case where the memory controller 50 orders the NAND flash memory 60 to perform an operation, the memory controller 50 sends a data group including commands and addresses (hereinafter, also referred to as memory command set) to the NAND flash memory 60. In a case where the memory controller 50 orders the NAND flash memory 60 to write data, the memory command set further includes data to be written.

In addition to the above configuration, the memory controller 50 may include other configurations such as an ECC circuit (not shown) for detecting and correcting errors in data.

The NAND flash memory 60 is a nonvolatile semiconductor memory device. The NAND flash memory 60 can store data substantially in a nonvolatile manner. Hereinafter, the NAND flash memory 60 is also simply referred to as flash memory 60.

The flash memory 60 includes a plurality of memory chips 600 and a bridge chip 650.

Each memory chip 600 includes a memory cell array 601 and a CMOS circuit 602. The memory cell array 601 is a data storage area. The CMOS circuit 602 is a circuit group to control various operations of the memory cell array 601. The data sent from the memory controller 50 is written in the memory cell array 601. Data requested from the memory controller 50 is read from the memory cell array 601. A plurality of chip groups GR each including the predetermined number of memory chips 600 communicates with the bridge chip 650 via the corresponding one of the channels Ch. The memory chips 600 are accessed per channel Ch.

The bridge chip 650 includes a device responsible for communication between the memory controller 50 and each flash memory 60. For example, the bridge chip 650 is a semiconductor chip independent of the memory controller 50 and the memory chip 600. The bridge chip 650 and the memory chips 600 can be configured as a package device. However, the bridge chip 650 may be provided as a package device separate from the memory chip 600.

The flash memory 60 communicates with the memory controller 50 through the bridge chip 650. Communication between the flash memory 60 and the memory controller 50 is supported by a NAND interface standard such as a toggle DDR standard or an ONFi standard. For example, a command latch enable signal CLE, an address latch enable signal ALE, a write enable signal WEn, a read enable signal REn, a ready/busy signal RBn, a data strobe signal DQS, an input/output signal DQ, and the like are used for communication between the flash memory 60 and the memory controller 50.

The command latch enable signal CLE is a signal indicating that the input/output signal DQ received by the flash memory 60 is a command. The address latch enable signal ALE is a signal indicating that the signal DQ received by the flash memory 60 is an address. The chip enable signal CEn is a signal to set the memory chip 600 to be accessed to an enable state. The write enable signal WEn is a signal to order the flash memory 60 to input the input/output signal DQ. The read enable signal REn is a signal to order the flash memory 60 to output the input/output signal DQ. The ready/busy signal RBn is a signal to notify, from the flash memory 60 to the memory controller 50, whether the flash memory 60 is in a ready state for accepting an order from the memory controller 50 or in a busy state for not accepting an order. The input/output signal DQ is, for example, a signal set having an 8-bit width. The input/output signal DQ may include a command, an address, data, and the like.

The bridge chip 650 includes interface circuits 651 and 654, a control circuit 652, a buffer memory 653, and the like.

The interface circuit (bridge interface (bridge I/F) circuit) 651 communicates with the memory controller 50 in parallel transmission. The bridge interface circuit 651 transmits or receives the signals CLE, ALE, CEn, WEn, REn, RBn, DQ, and DQS.

The control circuit 652 controls various operations in the bridge chip 650. For example, the control circuit 652 performs queuing of a command, analysis and generation of a command, checking of the execution state of a command, generation of a control signal, and the like. For example, the control circuit 652 generates data strobe signal DQS in response to the read enable signal REn.

The buffer memory 653 temporarily stores data to be written to the memory chip 600 or data read from the memory chip 600.

The interface circuit (channel interface (channel I/F) circuit) 654 communicates with the corresponding chip group GR via the channel Ch by parallel transmission. The channel interface circuit 654 sends a command, an address, and data to the chip group GR. The channel interface circuit 654 receives data from the chip group GR. The channel interface circuit 654 sends various signals CLE, ALE, CEn, WEn, REn, RBn, and DQS to the chip group GR. The channel interface circuit 654 sends or receives the input/output signal DQ to or from the chip group GR.

The bridge chip 650 may include a device configured to convert a signal transmitted from the memory controller 50 by serial transmission into parallel transmission in the flash memory 60.

The transmission circuit 11 as the semiconductor circuit of the embodiment and the transmitter TX are provided in the interface circuits 54 and 55 of the memory controller 50 and the interface circuits 651 and 654 of the bridge chip 650.

In the interface circuits 54 and 55 of the memory controller 50, the transmission circuit 11 includes the transmitter TX of the embodiment in a physical layer (PHY layer). In the interface circuits 651 and 654 of the bridge chip 650, the transmission circuit 11 includes the transmitter TX of the embodiment in the physical layer. In the interface circuits 54, 55, 651, and 654, the reception circuit 20 includes a receiver RX in the PHY layer.

For example, between the memory controller 50 and the flash memory 60, the transmitter TX and the receiver RX are used for relatively high-speed data transfer of 3 Gbps or more.

The transmission circuit 11 and the transmitter TX of the embodiment may be applied to the interface circuit 42 of the host 4.

In the memory system 5 and the NAND flash memory 60 of the application example, the transmission circuit 11 and the transmitter TX of the embodiment can suppress the influence of crosstalk such as jitter. As a result, the transmission circuit 11 of the embodiment can improve the reliability of data transfer in the memory system 5.

The transmission circuit 11 and the transmitter TX of the embodiment may be applied to a system (device) other than a memory system. For example, the transmission circuit 11 and the transmitter TX of the embodiment can be applied to a wireless communication system or a computing system including a plurality of processors.

### (6) Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor circuit comprising:
a detection unit that detects a first signal waveform of a first input signal on a first communication path and a second signal waveform of a second input signal on a second communication path, which is different from the first communication path;
a signal generation unit that generates a control signal based on the detected first and second signal waveforms; and
a first driver unit that outputs an output signal corresponding to the first input signal at a driver strength based on the control signal.

2. The semiconductor circuit according to claim 1, wherein
in a case where the first signal waveform is in a first change state and the second signal waveform is in a non-change state, the signal generation unit sets the driver strength of the control signal to a first driver strength,
in a case where the first signal waveform is in the first change state and the second signal waveform is in the first change state, the signal generation unit sets the driver strength of the control signal to a second driver strength, which is higher than the first driver strength, and
in a case where the first signal waveform is in the first change state and the second signal waveform is in a second change state, which is different from the first change state, the signal generation unit sets the driver strength of the control signal to a third driver strength, which is lower than the first driver strength.

3. The semiconductor circuit according to claim 1, wherein
the detection unit includes
a first logic gate that detects the first signal waveform in a first change state based on a signal level of the first input signal at a first time and a signal level of the first input signal at a second time, which is prior to the first time,
a second logic gate that detects the second signal waveform in the first change state based on a signal level of the second input signal at the first time and a signal level of the second input signal at the second time,
a third logic gate that detects the first signal waveform in a second change state, which is different from the first change state, based on the signal level of the first input signal at the first time and the signal level of the first input signal at the second time, and
a fourth logic gate that detects the second signal waveform in the second change state based on the signal level of the second input signal at the first time and the signal level of the second input signal at the second time.

4. The semiconductor circuit according to claim 1, wherein
the signal generation unit includes
a fifth logic gate that sets a first value of the control signal based on a first change state of the first signal waveform and the first change state of the second signal waveform, and
a sixth logic gate that sets a second value of the control signal based on a second change state, which is different from the first change state, of the first signal waveform and the second change state of the second signal waveform.

5. The semiconductor circuit according to claim 4, further comprising:
a seventh logic gate that generates a first signal of the control signal based on a signal from the fifth logic gate and the first input signal; and
an eighth logic gate that generates a second signal of the control signal based on a signal from the sixth logic gate and the first input signal.

6. The semiconductor circuit according to claim 5, further comprising:
a second driver unit that controls a pull-up side of the first driver unit based on the first signal from the seventh logic gate; and
a third driver unit that controls a pull-down side of the first driver unit based on the second signal from the eighth logic gate.

7. The semiconductor circuit according to claim 1, wherein
the first driver unit includes
a first transistor having a first conductivity type and including a first gate that receives an inverted signal of the first input signal, a first end connected to a first voltage node, and a first other end connected to a first node that sends the output signal, and
a second transistor having a second conductivity type, which is different from the first conductivity type, and including a second gate that receives the inverted signal of the first input signal, a second end connected to the first node, and a second other end connected to a second voltage node.

8. The semiconductor circuit according to claim 1, wherein
the first driver unit includes
an inverter that receives an inverted signal of the first input signal,
a buffer that receives the inverted signal of the first input signal,
a first transistor having a first conductivity type and including a first gate connected to an output node of the inverter, a first end connected to a first voltage node, and a first other end connected to a first node that sends the output signal, and
a second transistor having the first conductivity type and including a second gate connected to an output node of the buffer, a second end connected to the first node, and a second other end connected to a second voltage node.

9. A memory device comprising:
a memory cell array that stores data; and
an interface circuit including the semiconductor circuit according to claim 1.

10. A memory system comprising:
a memory device including a memory cell array that stores data; and
a memory controller that includes an interface circuit including the semiconductor circuit according to claim 1 and is configured to control operation of the memory device.

11. A semiconductor circuit comprising:
a first detection unit that acquires a first detection signal indicating a detection result of a signal waveform of a first input signal on a first communication path;
a signal generation unit that generates a first control signal based on the first detection signal and a second detection signal indicating a detection result of a signal waveform of a second input signal on a second communication path;
an adjustment unit that adjusts an output timing of the first input signal based on the first control signal; and
a driver unit that outputs an output signal based on the first input signal from the adjustment unit.

12. The semiconductor circuit according to claim 11, wherein
the first detection unit includes
a first logic gate that detects a first change state of the first input signal based on a signal level of the first input signal at a first time and a signal level of the first input signal at a second time, which is prior to the first time, and
a second logic gate that detects a second change state, which is different from the first change state, of the first input signal based on the signal level of the first input signal at the first time and the signal level of the first input signal at the second time.

13. The semiconductor circuit according to claim 12, wherein
the first logic gate includes a first AND gate that has a first input node having positive logic and receiving the first input signal at the first time, and a second input node having negative logic and receiving the first input signal at the second time, and
the second logic gate includes a second AND gate that has a third input node having negative logic and receiving the first input signal at the first time, and a fourth input node having positive logic and receiving the first input signal at the second time.

14. The semiconductor circuit according to claim 11, wherein
the adjustment unit includes
an inverter that receives the first input signal,
a first transistor that includes a first gate receiving a first code of the first control signal and a first end connected to a first voltage node,
a second transistor that includes a second gate connected to an output node of the inverter, a second end connected to a first other end of the first transistor, and a second other end connected to a first node,
a third transistor that includes a third gate connected to the output node of the inverter and a third end connected to the first node, and
a fourth transistor that includes a fourth gate receiving a second code of the first control signal, a fourth end connected to a third other end of the third transistor, and a fourth other end connected to a second voltage node.

15. The semiconductor circuit according to claim 14, wherein
the adjustment unit further includes
a fifth transistor that includes a fifth gate connected to the output node of the inverter, a fifth end connected to the first voltage node, and a fifth other end connected to the first node, and
a sixth transistor that includes a sixth gate connected to the output node of the inverter, a sixth end connected to the first node, and a sixth other end connected to the second voltage node.

16. A memory device comprising:
a memory cell array that stores data; and
an interface circuit including the semiconductor circuit according to claim 11.

17. A memory system comprising:
a memory device including a memory cell array that stores data; and
a memory controller that includes an interface circuit including the semiconductor circuit according to claim 11 and is configured to control operation of the memory device.

18. A semiconductor circuit comprising:
a first driver unit that receives a first input signal on a first communication path;
a second driver unit that receives the first input signal via a first conversion unit;
a third driver unit that receives a second input signal on a second communication path;
a fourth driver unit that receives the second input signal via a second conversion unit; and
a calculation unit that calculates an output signal corresponding to the first input signal based on a signal from the first driver unit, a signal from the second driver unit, a signal from the third driver unit, and a signal from the fourth driver unit.

19. The semiconductor circuit according to claim 18, further comprising:
a fifth driver unit that receives a third input signal on a third communication path; and
a sixth driver unit that receives the third input signal via a fourth conversion unit,
wherein
the calculation unit calculates an output signal corresponding to the first input signal based on a signal from the first driver unit, a signal from the second driver unit, a signal from the third driver unit, a signal from the fourth driver unit, a signal from the fifth driver unit, and a signal from the sixth driver unit.
